(19) United States
(12) Patent Application Publication
(10) Pub. No.: US 2025/0307505 A1
(43) Pub. Date: Oct. 2, 2025

(54) FLUID NETWORK FRAMEWORK

(71) Applicant: Schlumberger Technology Corporation, Sugar Land, TX (US)

(72) Inventors: Dauren Polatbekov, Houston, TX (US); Per Irgens, Houston, TX (US)

(21) Appl. No.: 19/091,992

(22) Filed: Mar. 27, 2025

Related U.S. Application Data
(60) Provisional application No. 63/571,748, filed on Mar. 29, 2024.

(51) Int. Cl. G06F 30/28

(52) U.S. Cl. CPC G06F 30/28

(57) ABSTRACT

A method can include accessing a flow simulation model for a fluid network; receiving parameters for the fluid network; performing one or more flow simulations for the fluid network using the flow simulation model and the parameters to generate results; and generating result constructs, using the results, for optimization of the fluid network.

### RELATED APPLICATION

This application claims priority to and the benefit of a U.S. Provisional Application having Ser. No. 63/571,748, filed 29 Mar. 2024, which is incorporated by reference herein in its entirety.

### BACKGROUND

Production systems can provide for transportation of fluids from well locations to processing facilities, from processing facilities to well locations, etc. Such fluid may be single or multiphase and include one or more hydrocarbon fluids (e.g., oil, natural gas, etc.) and may include one or more other fluids (e.g., water, etc.). As an example, a system may include a substantial number of flowlines and pieces of production equipment, for example, interconnected at junctions to form a network, which may be referred to as a fluid production network.

### SUMMARY

A method can include accessing a flow simulation model for a fluid network; receiving parameters for the fluid network; performing one or more flow simulations for the fluid network using the flow simulation model and the parameters to generate results; and generating result constructs, using the results, for optimization of the fluid network. A system can include a processor; memory accessible by the processor; and processor-executable instructions stored in the memory where the instructions include instructions to instruct the system to: access a flow simulation model for a fluid network; receive parameters for the fluid network; perform one or more flow simulations for the fluid network using the flow simulation model and the parameters to generate results; and generate result constructs, using the results, for optimization of the fluid network. One or more computer-readable storage media can include computer-executable instructions executable by a computer, where the instructions include instructions to: access a flow simulation model for a fluid network; receive parameters for the fluid network; perform one or more flow simulations for the fluid network using the flow simulation model and the parameters to generate results; and generate result constructs, using the results, for optimization of the fluid network. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and advantages of the described implementations can be more readily understood by reference to the following description taken in conjunction with the accompanying drawings.

FIG. 1 illustrates an example field system that includes various components, an example of a method and an example of a device or system;

FIG. 2 illustrates an example of a system and an example of a ternary diagram with an example of an associated table of fluid properties;

FIG. 3 illustrates an example of a system;

FIG. 4 illustrates an example of a network, an example of a system and examples of instructions;

FIG. 5 illustrates an example of a method;

FIG. 6 illustrates an example of a system;

FIG. 7 illustrates examples of graphical user interfaces;

FIG. 8 illustrates an example of a method;

FIG. 9 illustrates an example of a graphical user interface;

FIG. 10 illustrates an example of a graphical user interface;

FIG. 11 illustrates an example of a graphical user interface;

FIG. 12 illustrates an example of a graphical user interface;

FIG. 13 illustrates an example of a graphical user interface;

FIG. 14 illustrates an example of a graphical user interface;

FIG. 15 illustrates an example of a graphical user interface;

FIG. 16 illustrates an example of a graphical user interface;

FIG. 17 illustrates an example of a graphical user interface;

FIG. 18 illustrates an example of a graphical user interface;

FIG. 19 illustrates an example of a graphical user interface;

FIG. 20 illustrates an example of a graphical user interface;

FIG. 21 illustrates an example of a graphical user interface;

FIG. 22 illustrates an example of a method and an example of a system;

and

FIG. 23 illustrates an example of a computing system.

### DETAILED DESCRIPTION

The following description includes the best mode presently contemplated for practicing the described implementations. This description is not to be taken in a limiting sense, but rather is made merely for the purpose of describing the general principles of the implementations. The scope of the described implementations should be ascertained with reference to the issued claims.

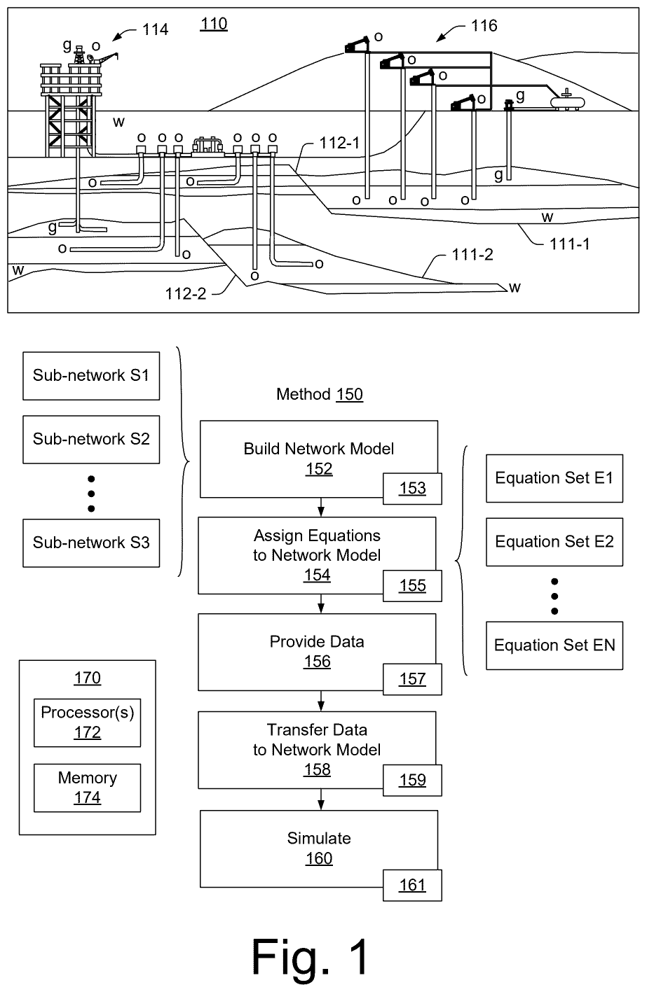

FIG. 1 shows an example of a geologic environment 110 that includes reservoirs 111-1 and 111-2, which may be faulted by faults 112-1 and 112-2, an example of a method 150 and an example of a device or system 170. FIG. 1 also shows some examples of offshore equipment 114 for oil and gas operations related to the reservoir 111-2 and onshore equipment 116 for oil and gas operations related to the reservoir 111-1.

As an example, a model may be made that models a geologic environment in combination with equipment, wells, etc. For example, a model may be a flow simulation model for use by a simulator to simulate flow in an oil, gas or oil and gas production system. Such a flow simulation model may include equations, for example, to model multiphase flow from a reservoir to a wellhead, from a wellhead to a reservoir, etc. A flow simulation model may also include equations that account for flowline and surface facility performance, for example, to perform a comprehensive production system analysis.

As an example, a flow simulation model may be a network model that includes various sub-networks specified using nodes, segments, branches, etc. As an example, a flow simulation model may be specified in a manner that provides for modeling of branched segments, multilateral segments, complex completions, intelligent downhole controls, etc. As an example, one or more portions of a production network (e.g., optionally sub-networks, etc.) or a group of signal components and/or controllers may be modeled as sub-models.

As an example, a system may provide for transportation of oil and gas fluids from well locations to processing facilities and may represent a substantial investment in infrastructure with both economic and environmental impact. Simulation of such a system, which may include hundreds or thousands of flow lines and production equipment interconnected at junctions to form a network, can involve multiphase flow science and, for example, use of engineering and mathematical techniques for large systems of equations.

As an example, a flow simulation model may include equations for performing nodal analysis, pressure-volume-temperature (PVT) analysis, gas lift analysis, erosion analysis, corrosion analysis, production analysis, injection analysis, etc. In such an example, one or more analyses may be based, in part, on a simulation of flow in a modeled network.

As to nodal analysis, it may provide for evaluation of well performance, for making decisions as to completions, etc. A nodal analysis may provide for an understanding of behavior of a system and optionally sensitivity of a system (e.g., production, injection, production and injection). For example, a system variable may be selected for investigation and a sensitivity analysis performed. Such an analysis may include plotting inflow and outflow of fluid at a nodal point or nodal points in the system, which may indicate where certain opportunities exist (e.g., for injection, for production, etc.).

A modeling framework may include instructions (e.g., processor-executable instructions) to facilitate generation of a flow simulation model. For example, instructions may provide for modeling completions for vertical wells, completions for horizontal wells, completions for fractured wells, etc. A modeling framework may include instructions for particular types of equations, for example, black-oil equations, equation-of-state (EOS) equations, etc. A modeling framework may include instructions for artificial lift, for example, to model fluid injection, fluid pumping, etc. As an example, consider a set of instructions (e.g., a component) that includes features for modeling one or more electric submersible pumps (ESPs) (e.g., based in part on pump performance curves, motors, cables, etc.).

As an example, an analysis using a flow simulation model may be a network analysis to: identify production bottlenecks and constraints; assess benefits of new wells, additional pipelines, compression systems, etc.; calculate deliverability from field gathering systems; predict pressure and temperature profiles through flow paths; or plan full-field development.

As an example, a flow simulation model may provide for analyses with respect to future times, for example, to allow for optimization of production equipment, injection equipment, etc. As an example, consider an optimal time-based and conditional-event logic representation for daily field development operations that can be used to evaluate drilling of new developmental wells, installing additional processing facilities over time, choke-adjusted wells to meet production and operating limits, shutting in of depleting wells as reservoir conditions decline, etc.

As to equations, sets of conservation equations for mass momentum and energy describing single, two or three phase flow (e.g., according to one or more of a LEDAFLOW (Kongsberg Oil & Gas Technologies AS, Sandvika, Norway), OLGA model (SLB, Houston, TX), TUFFP unified mechanistic models (Tulsa University Fluid Flow Projects, Tulsa, Oklahoma), etc.).

As to the method 150 of FIG. 1, it can include a build block 152 for building a network model that represents a production system for fluid; an assignment block 154 for assigning equations to sub-networks in the network model (e.g., where at least one of the sub-networks is optionally assigned equations formulated for solving for pressure and momentum implicitly and simultaneously, conservation mass and energy/temperature in separate stages), a provision block 156 for providing data; a transfer block 158 for transferring the data to the network model; and a simulation block 160 for simulating physical phenomena associated with the production system using the network model to provide simulation results.

The method 150 is shown in FIG. 1 in association with various computer-readable media (CRM) blocks 153, 155, 157, 159 and 161. Such blocks generally include instructions suitable for execution by one or more processors (or processing cores) 172 to instruct the computing device or system 170 to perform one or more actions. While various blocks are shown, a single medium may be configured with instructions to allow for, at least in part, performance of various actions of the method 150. As an example, a computer-readable medium (CRM) may be a computer-readable storage medium that is not a carrier wave, for example, such as a memory device 174 of the computing device or system 170, where the memory device 174 includes memory.

A production system can include equipment, for example, where a piece of equipment of the production system may be represented in a sub-network of a network model (e.g., optionally as a sub-model or sub-models, etc.) and, for example, assigned equations formulated to represent the piece of equipment. As an example, a piece of equipment may include an electric motor operatively coupled to a mechanism to move fluid (e.g., a pump, compressor, etc.). As an example, a piece of equipment may include a heater coupled to a power source, a fuel source, etc. (e.g., consider a steam generator). As an example, a piece of equipment may include a conduit for delivery of fluid where the fluid may be for delivery of heat energy (e.g., consider a steam injector). As an example, a piece of equipment may include a conduit for delivery of a substance (e.g., a chemical, a proppant, etc.).

As an example, a sub-network may be assigned equations formulated to represent fluid at or near a critical point, to represent heavy oil, to represent steam, to represent water or one or more other fluids (e.g., optionally subject to certain physical phenomena such as pressure, temperature, etc.).

As an example, a system can include a processor; a memory device having memory accessible by the processor; and processor-executable instructions stored in the memory of the memory device, the instructions executable to instruct the system to: build a network model that represents a production system for fluid, assign equations to sub-networks in the network model, provide data, transfer the data to the network model, and simulate physical phenomena associated with the production system using the network model to provide simulation results.

As an example, a system can include a sub-network assigned equations formulated for steam associated with equipment for an enhanced oil recovery (EOR) process (e.g., steam-assisted gravity drainage (SAGD) and/or other EOR process).

As an example, a system can include a sub-network that represents a piece of equipment of a production system by assigning that sub-network equations formulated to represent the piece of equipment. In such an example, the piece of equipment may include an electric motor operatively coupled to a mechanism to move fluid (e.g., a compressor, a pump, etc.).

As an example, one or more computer-readable media can include computer-executable instructions executable by a computer to instruct the computer to: receive simulation results for physical phenomena associated with a production system modeled by a network model; and analyze the simulation results.

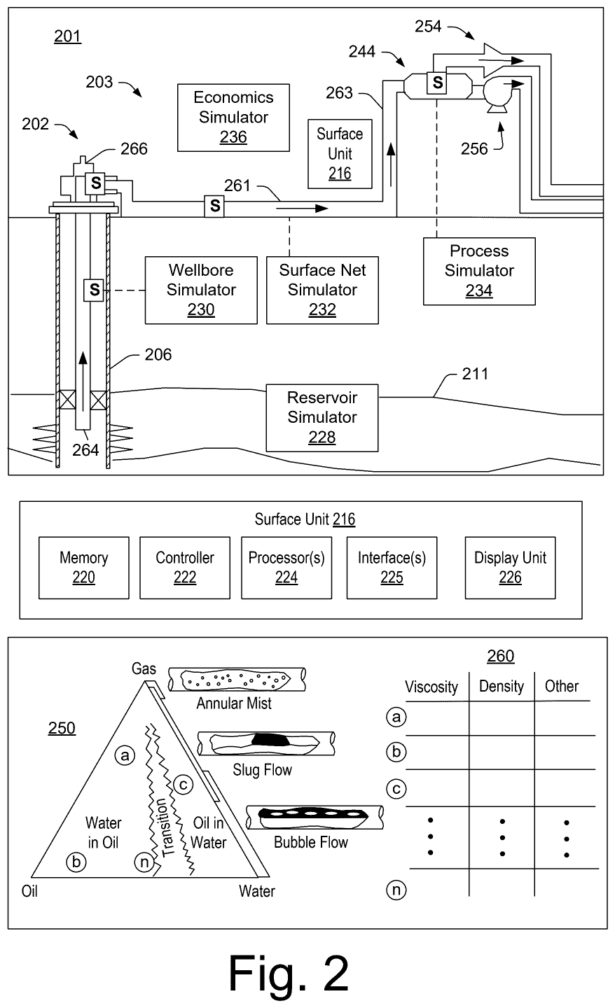

FIG. 2 shows an example of a schematic view of a portion of a geologic environment 201 that includes equipment and an example of a ternary diagram 250 with an example of a table 260 of associated fluid properties. As shown in FIG. 2, the environment 201 includes a wellsite 202, a network 203 and various examples of surface process equipment such as, for example, a separator 244, a compressor 254 and a pump 256. The wellsite 202 includes a wellbore 206 extending into earth as completed and prepared for production of fluid from a reservoir 211.

In the example of FIG. 2, wellbore production equipment 264 extends from a wellhead 266 of the wellsite 202 and to the reservoir 211 to draw fluid to the surface. As shown, the wellsite 202 is operatively connected to the network 203 via a transport line 261 (e.g., a pipeline) that can include a riser 263, which may include an S-shaped portion that may form a type of trap. As indicated by various arrows, fluid can flow from the reservoir 211, through the wellbore 206 and onto the network 203 and to a portion thereof 244. Fluid can then flow from the portion of the network 244, for example, to one or more fluid processing facilities.

In the example of FIG. 2, sensors(S) are located, for example, to monitor various parameters during operations. The sensors(S) may measure, for example, pressure, temperature, flowrate, composition, and other parameters of the reservoir, wellbore, gathering network, process facilities and/or other portions of an operation. As an example, the sensors(S) may be operatively connected to a surface unit 216 (e.g., to instruct the sensors to acquire data, to collect data from the sensors, etc.).

In the example of FIG. 2, the surface unit 216 can include various components, such as, for example, a memory device 220, a controller 222, one or more processors 224, one or more interfaces 225 and display unit 226 (e.g., for managing data, visualizing results of an analysis, etc.). As an example, data may be collected in the memory device 220 and processed by at least one of the one or more processor(s) 224 (e.g., for analysis, etc.). As an example, data may be collected from the sensors(S) and/or by one or more other sources. For example, data may be supplemented by historical data collected from other operations, user inputs, etc. As an example, analyzed data may be used in a decision-making process.

In the example of FIG. 2, a transceiver may be provided to allow communications between the surface unit 216 (e.g., via one or more of the interfaces 225) and one or more pieces of equipment in the environment 201 (e.g., one or more equipment interfaces, which may be wired and/or wireless). For example, the controller 222 may be used to actuate mechanisms in the environment 201 via the transceiver, optionally based on one or more decisions of a decision-making process. In such a manner, equipment in the environment 201 may be selectively adjusted based at least in part on collected data. Such adjustments may be made, for example, automatically based on computer protocol, manually by an operator or both. As an example, one or more well plans may be adjusted (e.g., to select optimum operating conditions, to avoid problems, etc.). In the example of FIG. 2, a network may be established that is a device network for purposes of transmission and receipt of information (e.g., via network interfaces).

To facilitate data analyses, one or more simulators may be implemented (e.g., optionally via the surface unit 216 or other unit, system, etc.). As an example, data fed into one or more simulators may be historical data, real time data or combinations thereof. As an example, simulation through one or more simulators may be repeated or adjusted based on the data received.

In the example of FIG. 2, simulators can include a reservoir simulator 228, a wellbore simulator 230, and a surface network simulator 232, a process simulator 234 and an economics simulator 236. As an example, the reservoir simulator 228 may be configured to solve for hydrocarbon flow rate (e.g., and optionally one or more pressures) through a reservoir and into one or more wellbores. As an example, the wellbore simulator 230 and surface network simulator 232 may be configured to solve for hydrocarbon flow rate (e.g., and optionally one or more pressures) through a wellbore and a surface gathering network of pipelines. As to the process simulator 234, it may be configured to model a processing plant where fluid containing hydrocarbons is separated into its constituent components (e.g., methane, ethane, propane, etc.), for example, and prepared for further distribution (e.g., transport via road, rail, pipe, etc.) and optionally sale. As an example, the economics simulator 236 may be configured to model costs associated with at least part of an operation. For example, consider MERAK framework (SLB, Houston, TX), which may provide for economic analyses.

In FIG. 2, the ternary diagram 250 includes vertices that represent single-phase gas, oil and water, while the sides represent two phase mixtures (e.g., gas-oil, oil-water and gas-water) and points within the triangle represents a three-phase mixture. The transition region indicates where the liquid fraction changes from water in oil to oil in water and vice versa (e.g., consider emulsions).

The ternary diagram 250 of FIG. 2 also indicates some examples of ranges of multiphase flow regimes, which may be affected by one or more factors such as, for example, temperature, pressure, viscosity, density, flowline orientation, etc. The example flow regimes include annular mist, slug flow and bubble flow; noting that other types of may occur (e.g., stratified, churn, disperse, etc.). Annular mist flow may be characterized by, for example, a layer of liquid on the wall of a pipe and droplets of liquid in a middle gas zone (e.g., mist). Slug flow may be characterized by, for example, a continuous liquid phase and a discontinuous liquid phase that is discontinuous due to separation by pockets of gas. Bubble flow may be characterized by, for example, two continuous liquid phases where at least one of the continuous liquid phases includes gas bubbles. The illustrative graphics of flow regimes in FIG. 2 correspond to flows in approximately horizontal conduits; noting that a conduit may be disposed at an angle other than horizontal and that various factors that can influence flow may depend on angle of a conduit. For example, the angle of a conduit with respect to gravity can have an influence on how fluid flows in the conduit.

The table 260 of FIG. 2 shows viscosity and density as fluid properties. As to one or more other properties, consider, for example, surface tension. As indicated, the table 260 can include information for points specified with respect to the ternary diagram 250. As an example, factors such as pressure, volume and temperature may be considered, for example, as to values of fluid properties, phases, flow regimes, etc.

As an example, information as to flow of fluid may be illustrated as a flow regime map that identifies flow patterns occurring in various parts of a parameter space defined by component flow rates. For example, consider flow rates such as volume fluxes, mass fluxes, momentum fluxes, or one or more other quantities. Boundaries between various flow patterns in a flow regime map may occur where a regime becomes unstable and where growth of such instability causes transition to another flow pattern. As in laminar-to-turbulent transition in single phase flow, multiphase transitions may be rather unpredictable as they may depend on otherwise minor features of the flow, such as the roughness of the walls or the entrainment and entrance conditions. Thus, as indicated in the ternary diagram 250, flow pattern boundaries may lack distinctiveness and exhibit transition zones.

As to properties, where fluid is single phase (e.g., water, oil or gas), a single value of viscosity may suffice for given conditions. However, where fluid is multiphase, two or more concurrent phases may occupy a flow space within a conduit (e.g., a pipe). In such an example, a single value of viscosity (e.g., or density) may not properly characterize the fluid in that flow space. Accordingly, as an example, a value or values of mixture viscosities may be used, for example, where a mixture value is a function of phase fraction(s) for fluid in a multiphase flow space.

As to surface tension (e.g., σ), it may be defined for gas and liquid, for example, where the liquid may be oil or water. Where two-phase liquid-liquid flow exists (e.g., water and oil), then σ may reflect the interfacial tension between oil and water (see, e.g., the slug flow regime and the bubble flow regime).

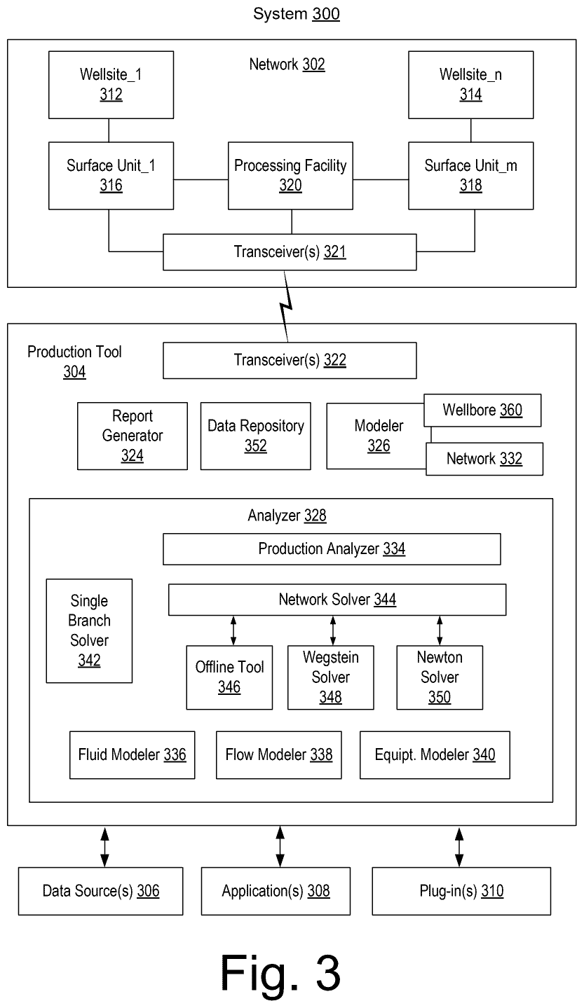

FIG. 3 shows an example of a schematic diagram of a production system 300 for performing oilfield production operations. As shown in the example of FIG. 3, the production system 300 can include an oilfield network 302, an oilfield production tool 304, one or more data sources 306, one or more oilfield application(s) 308, and one or more plug-in(s) 310. As an example, the oilfield network 302 can be an interconnection of pipes (e.g., conduits) that connects wellsites (e.g., a wellsite_1 312, a wellsite_n 314, etc.) to a processing facility 320. A pipe in the oilfield network 302 may be connected to a processing facility (e.g., a processing facility 320), a wellsite (e.g., the wellsite 1 312, the wellsite_n 314, etc.), and/or a junction in which pipes are connected. As an example, flow rate of fluid and/or gas into pipes may be adjustable; thus, certain pipes in the oilfield network 302 may be choked or closed so as to not allow fluid and/or gas through the pipe. A pipe may be considered open (e.g., optionally choked) when the pipe allows for flow of fluid and/or gas. As to a choke, choking may allow for adjusting one or more characteristics of a piece of flow equipment (e.g., a cross-sectional flow area, etc.), for example, for adjusting to fully open flow, for adjusting to choked flow and/or for adjusting to no flow (e.g., closed).

As an example, a choke may include an orifice that is used to control fluid flow rate or downstream system pressure. As an example, a choke may be provided in any of a variety of configurations (e.g., for fixed and/or adjustable modes of operation). As an example, an adjustable choke may enable fluid flow and pressure parameters to be changed to suit process or production requirements. As an example, a fixed choke may be configured for resistance to erosion under prolonged operation or production of abrasive fluids.

The oilfield network 302 may be a gathering network and/or an injection network. A gathering network may be an oilfield network used to obtain hydrocarbons from a wellsite (e.g., the wellsite_1 312, the wellsite_n 314, etc.). In a gathering network, hydrocarbons may flow from the wellsites to the processing facility 320. An injection network may be an oilfield network used to inject the wellsites with injection substances, such as water, carbon dioxide, and other chemicals that may be injected into the wellsites. In an injection network, the flow of the injection substance may flow towards the wellsite (e.g., toward the wellsite_1 312, the wellsite_n 314, etc.).

The oilfield network 302 may also include one or more surface units (e.g., a surface unit_1 316, a surface unit_m 318, etc.), for example, which may include a surface unit for each wellsite. Such surface units may include functionality to collect data from sensors (see, e.g., the surface unit 216 of FIG. 2). Such sensors may include sensors for measuring flow rate, water cut, gas lift rate, pressure, and/or other such variables related to measuring and monitoring hydrocarbon production. As shown, the oilfield network 302 can include one or more transceivers 321, for example, to receive information, to transmit information, to receive information and transmit information, etc. As an example, information may be received and/or transmitted via wire and/or wirelessly. As an example, information may be received and/or transmitted via a communications network such as, for example, the Internet, the Cloud, a cellular network, a satellite network, etc.

As an example, the oilfield production tool 304 may be connected to the oilfield network 302. The oilfield production tool 304 may be a simulator (e.g., a simulation framework) or a plug-in for a simulator (e.g., or other application(s)). The oilfield production tool 304 may include one or more transceivers 322, a report generator 324, an oilfield modeler 326, and an oilfield analyzer 328. As an example, the one or more transceivers 322 may be configured to receive information, to transmit information, to receive information and transmit information, etc. As an example, information may be received and/or transmitted via wire and/or wirelessly. As an example, information may be received and/or transmitted via a communications network such as, for example, the Internet, the Cloud, a cellular network, a satellite network, etc.

As an example, one or more of the one or more transceivers 322 may include functionality to collect oilfield data. The oilfield data may be data from sensors, historical data, or any other such data. One or more of the one or more transceivers 322 may also include functionality to interact with a user and display data such as a production result.

As an example, the report generator 324 can include functionality to produce graphical and textual reports. Such reports may show historical oilfield data, production models, production results, sensor data, aggregated oilfield data, or any other such type of data.

As an example, the data repository 352 may be a storage unit and/or device (e.g., a file system, database, collection of tables, or any other storage mechanism) for storing data, such as the production results, sensor data, aggregated oilfield data, or any other such type of data. As an example, the data repository 352 may include multiple different storage units and/or hardware devices. Such multiple different storage units and/or devices may or may not be of the same type or located at the same physical site. As an example, the data repository 352, or a portion thereof, may be secured via one or more security protocols, whether physical, algorithmic or a combination thereof (e.g., data encryption, secure device access, secure communication, etc.).

In the example of FIG. 3, the oilfield modeler 326 can include functionality to create a model of a wellbore and an oilfield network. As shown, the oilfield modeler 326 includes a wellbore modeler 360 and a network modeler 332. As an example, the wellbore modeler 360 can allow a user to create a graphical wellbore model or single branch model. As an example, a wellbore model can define operating parameters (e.g., actual, theoretical, etc.) of a wellbore (e.g., pressure, flow rate, etc.). As an example, a single branch model may define operating parameters of a single branch in an oilfield network.

As to the network modeler 332, it may allow a user to create a graphical network model that combines wellbore models and/or single branch models. As an example, the network modeler 332 and/or wellbore modeler 360 may model pipes in the oilfield network 302 as branches of the oilfield network 302 (e.g., optionally as one or more segments, optionally with one or more nodes, etc.). In such an example, each branch may be connected to a wellsite or a junction. A junction may be defined as a group of two or more pipes that intersect at a particular location (e.g., a junction may be a node or a type of node).

As an example, a modeled oilfield network may be formed as a combination of sub-networks. In such an example, a sub-network may be defined as a portion of an oilfield network. For example, a sub-network may be connected to the oilfield network 302 using at least one branch. Sub-networks may be a group of connected wellsites, branches, and junctions. As an example, sub-networks may be disjoint (e.g., branches and wellsites in one sub-network may not exist in another sub-network).

As an example, the oilfield analyzer 328 can include functionality to analyze the oilfield network 302 and generate a production result for the oilfield network 302. As shown in the example of FIG. 3, the oilfield analyzer 328 may include one or more of the following: a production analyzer 334, a fluid modeler 336, a flow modeler 338, an equipment modeler 340, a single branch solver 342, a network solver 344, a Wegstein solver 348, a Newton solver 350, and an offline tool 346.

As an example, the production analyzer 334 can include functionality to receive a workflow request and interact with the single branch solver 342 and/or the network solver 344 based on particular aspects of the workflow. For example, the workflow may include a nodal analysis to analyze a wellsite or junction of branches, pressure and temperature profile, model calibration, gas lift design, gas lift optimization, network analysis, and other such workflows.

As an example, the fluid modeler 336 can include functionality to calculate fluid properties (e.g., phases present, densities, viscosities, etc.) using one or more compositional and/or black-oil fluid models. The fluid modeler 336 may include functionality to model oil, gas, water, hydrate, wax, and asphaltene phases. As an example, the flow modeler 338 can include functionality to calculate pressure drop in pipes (e.g., pipes, tubing, etc.) using industry standard multiphase flow correlations. As an example, the equipment modeler 340 can include functionality to calculate pressure, temperature and flow changes in equipment pieces (e.g., chokes, pumps, compressors, etc.). As an example, one or more substances may be introduced via a network for purposes of managing asphaltenes, waxes, etc. As an example, a modeler may include functionality to model interaction between one or more substances and fluid (e.g., including material present in the fluid).

As an example, the single branch solver 342 may include functionality to calculate the flow, pressure drop and changes to fluid temperature in a wellbore or a single flowline branch given various inputs.

As an example, the network solver 344 can includes functionality calculate a flow rate, pressure drop and changes to fluid temperature throughout the oilfield network 302. The network solver 344 may be configured to connect to the offline tool 346, the Wegstein solver 348, and the Newton solver 350. As an example, alternatively or additionally, one or more other solvers may be provided, for example, consider a sequential linear programming solver (SLP), a sequential quadratic programming solver (SQP), etc. As an example, a solver may be part of the production tool 304, part of the analyzer 328 of the production tool 304, part of a system to which the production tool 304 may be operatively coupled, etc.

As an example, the offline tool 346 may include a wells offline tool and a branches offline tool. A wells offline tool may include functionality to generate a production model using the single branch solver 342 for a wellsite or branch. A branches offline tool may include functionality to generate a production model for a sub-network using the production model for a wellsite, a single branch, or a sub-network of the sub-network.

As an example, a production model may be capable of providing a description of a wellsite with respect to various operational conditions. A production model may include one or more production functions that may be combined, for example, where each production function may be a function of variables related to the production of hydrocarbons. For example, a production function may be a function of flow rate and/or pressure and/or temperature. Further, a production function may account for environmental conditions related to a sub-network of the oilfield network 302, such as changes in elevation (e.g., for gravity head, pressure, etc.), diameters of pipes, combination of pipes, changes in pressure resulting from joining pipes and changes pipe or production environmental data such as ambient temperature (ambient fluid velocity etc.). A production model may provide estimates of flow rate for a wellsite or sub-network of an oilfield network.

As an example, one or more separate production functions may exist that can account for changes in one or more values of an operational condition. An operational condition may identify a property of hydrocarbons or injection substance. For example, an operational condition may include a watercut (WC), reservoir pressure, gas lift rate, etc. Other operational conditions, variables, environmental conditions may be considered.

As to the network solver 344, in the example of FIG. 3, it is shown as being connected to the Wegstein solver 348 and/or the Newton solver 350. The Wegstein solver 348 and the Newton solver 350 include functionality to combine a production model for several sub-networks to create a production result that may be used to plan an oilfield network, optimize flow rates of wellsites in an oilfield network, and/or identify and address faulty components within an oilfield network. The Wegstein solver 348 can use an iterative method with Wegstein acceleration.

An oilfield network may be solved by identifying pressure drop (e.g., pressure differential), for example, through use of momentum equations. As an example, an equation for pressure differential may account for factors such as fluid potential energy (e.g., hydrostatic pressure), friction (e.g., shear stress between conduit wall and fluid), and acceleration (e.g., change in fluid velocity). As an example, an equation may be expressed in terms of static reservoir pressure, a flowing bottom hole pressure and flowrate. As an example, equations may account for vertical, horizontal or angled arrangements of equipment. Various examples of equations may be found in a dynamic multiphase flow simulator such as the simulator of the OLGA simulation framework (SLB, Houston, TX), which may be implemented for design and diagnostic analysis of oil and gas production systems. As an example, a simulation framework may include one or more sets of instructions for building a model; for fluid and multiphase flow modeling; for reservoir, well and completion modeling; for field equipment modeling; and for operations (e.g., artificial lift, gas lift, wax prediction, nodal analysis, network analysis, field planning, multi-well analysis, etc.).

As an example, a system may implement equations that include dynamic conservation equations for momentum, mass and energy. As an example, pressure and momentum can be solved implicitly and simultaneously and, for example, conservation of mass and energy (e.g., temperature) may be solved in succeeding separate stages.

As an example, an equation for pressure differential can account for factors such as fluid potential energy (e.g., hydrostatic pressure), friction (e.g., shear stress between conduit wall and fluid), and acceleration (e.g., change in fluid velocity). In addition, as mentioned, equations can be used to take into account dynamic aspects.

For example, equations can account for time and forces to accelerate and decelerate fluid (e.g., and objects) inserted into multiphase flow (e.g., consider pigs, etc.). As an example, an approach may consider the time it takes to conserve mass and energy (e.g., an amount of time it takes to drain a system, pipeline or vessel). As an example, an approach may consider ramp-up time for production, for example, from one production rate to another production rate, etc. As an example, an approach may consider time it takes before a first condensate appears at an outlet of a production network during startup, etc.

As an example, an equation for a pressure differential (e.g., ΔP) may be rearranged to solve for flow rate (e.g., Q), where the equation may include the Reynolds number (e.g., Re, a dimensionless ratio of inertial to viscous forces), one or more friction factors (e.g., which may depend on flow regime), etc.

Through use of equations for flow into and out of a branch and equating to zero, a linear matrix in unknown pressures may be obtained. As an example, fixed flow branches (i.e., branches in which the flow does not change) may be solved directly for the node pressures.

As an example, a method can include defining variables and residual equations as well as branches in an oilfield network that may include a number of equipment items. As an example, a branch may be divided into sub-branches with each sub-branch containing a single equipment item. As an example, a new node may be used to join each pair of sub-branches. In this example, primary Newton-Raphson variables can include a flow (Q_{ib}) in each sub-branch in the network and a pressure Pin at each node in the network. In this example, temperature (or enthalpy) and composition may be treated as secondary variables.

As an example, residual equations may include a branch residual, an internal node residual, and a boundary condition. In such an example, a branch residual for a sub-branch relates the branch flow to the pressure at the branch inlet node and the pressure at the outlet node. As an example, internal node residuals can define where total flow into a node is equal to total flow out of the node.

As an example, determining an initial solution may be performed using a production model where for each subsequent iteration, a Jacobian matrix is calculated. The values of the Jacobian matrix may be used to solve a Jacobian equation for the Newton-Raphson update. To solve the Jacobian equation, one or more types of matrix solvers may be used.

In the example of FIG. 3, the one or more data sources 306 include one or more types of repositories for data. For example, the one or more data sources 306 may be Internet sources, sources from a company having ties to the oilfield network 302, or any other location in which data may be obtained. The data may include historical data, data collected from other oilfield networks, data collected from the oilfield network being modeled, data describing environmental or operational conditions.

In the example of FIG. 3, the one or more oilfield applications 308 may be applications related to the production of hydrocarbons. The one or more oilfield applications 308 may include functionality to evaluate a formation, manage drilling operations, evaluate seismic data, evaluate workflows in the oilfield, perform simulations, or perform any other oilfield related function. In the example of FIG. 3, the one or more plug-ins 310 may allow integration with packages such as, for example, a TUFPP model, an Infochem Multiflash model (Infochem Computer Services Ltd., London, UK), an equipment model, etc. (e.g., consider one or more simulators like HYSYS (AspenTech, Burlington, Massachusetts), UNISIM (Honeywell, Morristown, New Jersey), etc.).

While the example of FIG. 3 shows the oilfield production tool 304 as a separate component from the oilfield network 302, the oilfield production tool 304 may alternatively be part of the oilfield network 302. For example, the oilfield production tool 304 may be located at one of the wellsites (e.g., the wellsite 1 312, the wellsite n 314, etc.), at the processing facility 320, or any other location in the oilfield network 302. As another example, the oilfield production tool 304 may exist separate from the oilfield network 302, such as when the oilfield production tool 304 is used to plan the oilfield network.

Various types of numerical solution schemes may be characterized as being explicit or implicit. For example, when a direct computation of dependent variables can be made in terms of known quantities, a scheme may be characterized as explicit. Whereas, when dependent variables are defined by coupled sets of equations, and either a matrix or iterative technique is implemented to obtain a solution, a scheme may be characterized as implicit.

As an example, a scheme may be characterized as adaptive implicit (“AIM”). An AIM scheme may adapt, for example, based on one or more gradients as to one or more variables, properties, etc. of a model. For example, where a model of a subterranean environment includes a region where porosity varies rapidly with respect to one or more physical dimensions (e.g., x, y, or z), a solution for one or more variables in that region may be modeled using an implicit scheme while an overall solution for the model also includes an explicit scheme (e.g., for one or more other regions for the same one or more variables).

As an example, a scheme may be implemented as part of the ECLIPSE reservoir simulator and/or the INTERSECT reservoir simulator (SLB, Houston, TX). As an example, the aforementioned OLGA simulator may include an interface that allows for interoperability with an ECLIPSE simulator. The ECLIPSE reservoir simulator may implement a fully implicit scheme or an implicit-explicit scheme that is implicit in pressure and explicit in saturation, known as IMPES. In the fully implicit scheme, values for both pressure and saturation are provided at the end of each simulation time-step; whereas, the IMPES scheme uses saturation values from the beginning of the time-step to solve for pressure values at the end of the time-step. In such examples, a reservoir simulator iterates until pressures values in grid blocks of a model of the reservoir being simulated have reached some internally consistent solution. However, a solution may be difficult to find if saturation (which the IMPES scheme assumes is constant within a time-step) changes rapidly during that time-step (e.g., a large percentage change in grid block values for saturation). The IMPES scheme may be able to cope with such an issue by decreasing “length” (e.g., duration) of the time-step but at the cost of more time-steps (e.g., in an effort to achieve a more stable solution).

The aforementioned fully implicit scheme may be a more stable option with saturation and pressure being obtained simultaneously so as any difference between their values for one time-step and a next time-step does not disturb a solution process as much as when compared to the IMPES scheme. Thus, in a fully implicit scheme, the “length” (e.g., duration) of a time-step may be larger but it also means that the fully implicit scheme may take additional processing time to achieve solutions (e.g., in comparison with an IMPES scheme). However, in a reservoir where properties change rapidly, a fully implicit scheme may provide a solution in less computational time than an IMPES scheme, even though an iteration of the fully implicit scheme may take longer to complete when compared to an iteration of the IMPES scheme.

As mentioned, a production system can provide for transportation of oil and gas fluids from well locations along flowlines which are interconnected at junctions to combine fluids from many wells for delivery to a processing facility. Along these flowlines (including at one or more ends of a flowline), production equipment may be inserted to modify the flowing characteristics like flow rate, pressure, composition and temperature. As an example, a boundary condition may depend on a type of equipment, operation of a piece of equipment, etc.

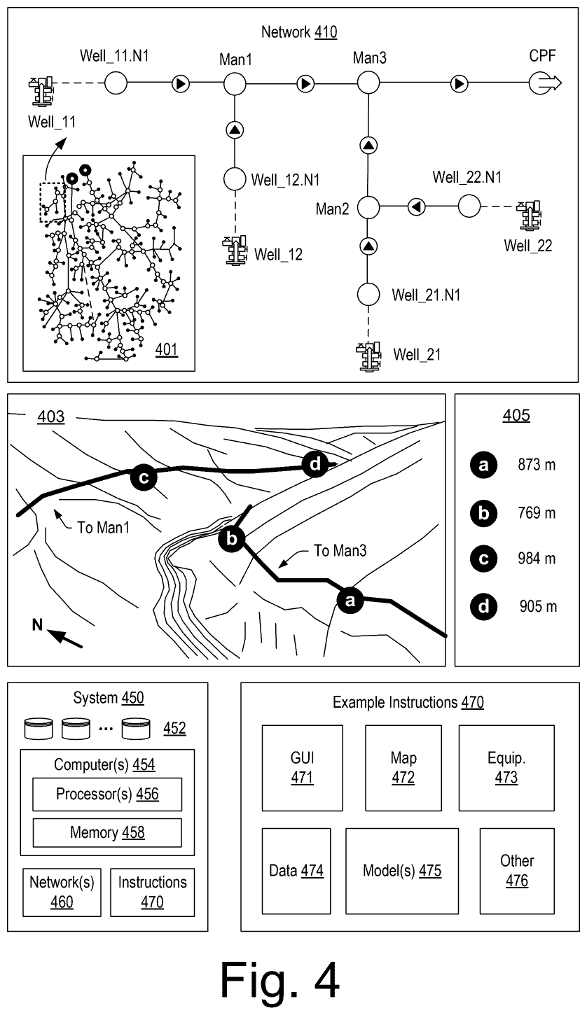

FIG. 4 shows an example of a relatively small production system network 410 (e.g., optionally a portion of a larger network 401), an example of a system 450 and examples of instructions 470. As shown, the network 410 forms somewhat of a tree-like structure where flowlines represent branches (e.g., segments) and junctions represent nodes. As shown in FIG. 4, the network 410 provides for transportation of oil and gas fluids from well locations along flowlines interconnected at junctions with final delivery at a central processing facility.

In the example of FIG. 4, various portions of the network 410 may include conduit. For example, consider a perspective view of a geologic environment 403 that includes two conduits which may be a conduit to Man1 and a conduit to Man3 in the network 410. The conduits may be specified at various points by characteristics, which may be characteristics of the environment, characteristics of the conduits, characteristics of fluid in the conduits, etc. For example, consider conduit elevation, which may allow for determination of conduit inclination. As an example, consider conduit cross-sectional flow area, which may be defined by one or more parameters such as, for example, a conduit diameter. As an example, consider fluid that may flow in a conduit where the fluid may be characterized at least in part by a property such as, for example, viscosity (see, e.g., the ternary diagram 250 and the table 260 of FIG. 2 and approaches to multiphase properties, etc.). As an example, thermal conditions may optionally be considered such as, for example, latent heat, heat transfer, etc. As an example, thermal conditions may depend on insulation of equipment, temperature of an environment, wind, sun, rain, snow, etc. Such factors may be considered when assessing an existing network, developing a network, extending a network, etc.

As an example, given information of operating condition(s) at boundary nodes (e.g., where fluid enters and exists the system) and the physical environment between them (e.g., geographical location, elevation, ambient temperature, etc.), a production engineer may aim to design a production system that meets business and regulatory requirements constrained to operating limits of available equipment.

As an example, a method can include implementing one or more components to simulate steady state operation of a production system, for example, as including a network (e.g., as a sub-network, etc.) as in the example of FIG. 4 (also see, e.g., FIG. 1). Such a method may include simulating the steady state operation over a selected range of operating conditions and configurations (e.g., optionally a broadest reasonable range).

As explained, a production system may provide for transportation of oil and gas fluids from well locations to a processing facility and can represent a substantial investment in infrastructure with both economic and environmental impact. Simulation of such a system, which may include hundreds or thousands of flow lines and production equipment interconnected at junctions to form a network, can be complex and involve multiphase flow science and engineering and mathematical methods to provide solutions (e.g., by solving large systems of non-linear equations). Factors associated with solid formation, corrosion and erosion, and environmental impact may increase complexity and cost.

As shown in FIG. 4, the example system 450 includes one or more information storage devices 452, one or more computers 454, one or more networks 460 and instructions 470 (e.g., organized as one or more sets of instructions). As to the one or more computers 454, each computer may include one or more processors (e.g., or processing cores) 456 and memory 458 for storing the instructions 470 (e.g., one or more sets of instructions), for example, executable by at least one of the one or more processors. As an example, a computer may include one or more network interfaces (e.g., wired or wireless), one or more graphics cards, a display interface (e.g., wired or wireless), etc. As an example, imagery such as surface imagery (e.g., satellite, geological, geophysical, etc.) may be stored, processed, communicated, etc. As an example, data may include SAR data, GPS data, etc. and may be stored, for example, in one or more of the storage devices 452. As an example, information that may be stored in one or more of the storage devices 452 may include information about equipment, location of equipment, orientation of equipment, fluid characteristics, etc.

As an example, the instructions 470 can include instructions (e.g., stored in the memory 458) executable by at least one of the one or more processors 456 to instruct the system 450 to perform various actions. As an example, the system 450 may be configured such that the instructions 470 provide for establishing a framework, for example, that can perform network modeling. As an example, one or more methods, techniques, etc. may be performed using one or more sets of instructions, which may be, for example, the instructions 470 of FIG. 4.

FIG. 4 shows examples of the instructions 470 as including a graphical user interface (GUI) component 471, a map component 472, an equipment component 473, a data component 474 (e.g., for measured data, synthetic data, etc.), a modeling component 475, and one or more other component 476 where a component can be or include a set of instructions.

As an example, a component can include instructions to instruct a system to render terrain and equipment locations to a display (e.g., via the GUI component 471, the map component 472, the equipment component 473, etc.); receive data for at least a portion of a network (e.g., via the data component 474); analyze the data with respect to a model associated with the terrain and the equipment locations (e.g., via the modeling component 475); and render information to the display based at least in part on an analysis (e.g., via the GUI component 471, a report component, etc.).

As an example, a framework may be implemented using various features of a system such as, for example, the system 450 of FIG. 4. As an example, one or more sets of instructions may be provided that include instructions that may be executed by a processor or processors. As an example, instructions may be provided for execution of instructions in parallel, for example, to consider multiple features of a network or networks that may be associated with a geologic environment such as the geologic environment 110 of FIG. 1.

Production systems for oil and gas often cover multiple wells tied back to a manifold, platform or onshore, etc. (e.g., consider a sub-sea manifold, a wellhead platform, a land-based manifold, etc.). At a manifold or wellhead platform, production from different wells may be co-mingled (e.g., merged, mixed, etc.) and fed to one or more multiphase pipelines that can transport fluid, for example, to topside or central processing facilities. As an example, multiple manifolds and wellhead platforms may feed one topside/central processing facility. As an example, produced fluid from a topside/central processing facilities may again be fed to export pipelines for gas and/or oil to feed a market or a chemical processing plant.

As an example, a fluid production network can include a substantially vertical conduit and a substantially horizontal conduit and/or a substantially vertical conduit and/or a conduit that is neither substantially horizontal nor substantially vertical. As an example, a substantially vertical conduit can be oriented at an angle with respect to horizontal that is greater than about 50 degrees. As an example, a substantially horizontal conduit can be oriented at an angle with respect to horizontal that is less than about 40 degrees (e.g., between −40 degrees and +40 degrees depending on whether sloping down or up with respect to a direction, which may be a flow direction). As an example, a model or models can account for orientation, for example, as one or more parameters of a model or models.

As an example, a fluid production network can be or include a multiphase fluid production network. As an example, values output via a model-based framework can include values for fluid flow variables at a plurality of different times (e.g., single phase, multiphase, etc.).

As an example, a framework may be optionally coupled to one or more data transmission systems, which may include, for example, a supervisory control and data acquisition (SCADA) system. For example, a framework may provide for monitoring a production system using one or more models where, responsive to model-based results, one or more notifications (e.g., instructions, commands, alarms, etc.) may be communicated via one or more data transmission systems. As an example, a SCADA system can include equipment for monitoring and control, which may operate, for example, with coded signals over communication channels (e.g., a communication channel per remote station, etc.).

As mentioned, slug flow can be associated with gas in a pipeline. Gas can be naturally occurring and/or injected. For example, consider an artificial lift technique that utilizes gas, which may be injected at one or more points in a system that can include downhole points, underwater points and/or surface points.

Flow assurance problems in oil and gas production networks encompass various challenges, which may include, for example, one or more of hydrate formation, wax and asphaltene deposition, emulsion formation, corrosion, scale formation, slugging, and sand production. Such challenges tend to not be static in nature. As such, the dynamic nature of such challenges may be taken into account and coupled with forecasted production from wells supported by one or more networks. In combination, multiple issues may lead to reduced flow capacity, flow disruptions, equipment damage, increased operational costs, etc.

As an example, a fluid network framework may provide for addressing flow assurance, for example, to help maintain and/or improve efficient and reliable operation of oil and gas production and transportation networks. In various instances, one or more field operations may be called for and/or implemented. For example, consider one or more field operations as to chemical treatments, insulation, mechanical pigging, monitoring, which may provide for risk mitigation, assurance as to uninterrupted flow, etc. As an example, a fluid network framework can be a computational framework that may include local and/or remote circuitry where, for example, one or more interfaces may provide for receipt of data and issuance of commands, which may include control commands that can provide for control of field equipment.

As an example, a fluid network framework may operation as a production advisor that may empower users with automation of one or more production network forecasting workflows. In such an example, the framework may provide for updating one or more models with operational data, running batch simulations, retrieving, analyzing results, issuing commands, etc.

As an example, a fluid network framework may include or be operatively coupled to a simulation framework such as, for example, a multiphase flow simulation framework. As an example, the PIPESIM framework or simulator (SLB, Houston, TX) may provide for multiphase flow simulation (e.g., as a computational simulation engine or simulator).

The PIPESIM simulator includes solvers that may provide simulation results such as, for example, multiphase flow results (e.g., from a reservoir to a wellhead and beyond, etc.), flowline and surface facility performance, etc. The PIPESIM simulator may be integrated, for example, with the AVOCET production operations framework (SLB, Houston, TX). As an example, a reservoir or reservoirs may be simulated with respect to one or more enhanced recovery techniques (e.g., consider a thermal process such as steam-assisted gravity drainage (SAGD), etc.). As an example, the PIPESIM simulator may be an optimizer that can optimize one or more operational scenarios at least in part via simulation of physical phenomena.

As an example, a simulator or simulation may include reservoir simulation where a reservoir is in fluid communication with one or more conduits (e.g., wells, etc.). For example, consider the ECLIPSE simulator, the INTERSECT simulator, etc., as to reservoir simulation which may be operatively coupled to an OGLA framework, a PIPESIM framework, etc.

The PIPESIM simulator includes three-phase mechanistic models, enhancements to heat transfer modeling, and comprehensive PVT modeling options. The PIPESIM simulator provides ESRI-supported GIS map canvases for spatial representation of wells, equipment, and networks. As an example, a network may be built on a GIS canvas or generated automatically using a GIS shape file. As an example, an interactive graphical wellbore may be rendered as part of a graphical user interface (GUI) to enable rapid well model building and analysis. As an example, the PIPESIM simulator may provide for implementation of a parallel network solver to spread the computational load across a number of processors.

As an example, the PIPESIM simulator may provide for improved flow assurance. The PIPESIM simulator may provide for implementation of one or more steady-state flow assurance workflows for one or more tasks (e.g., front-end system design, production operations, etc.). As an example, flow assurance capabilities of the PIPESIM simulator may provide for improved operations such as, for example, safe and effective fluid transport, spanning tasks from sizing of facilities, pipelines, and lift systems, to ensuring effective liquids and solids management, to well and pipeline integrity. The PIPESIM simulator can provide shared heat transfer, multiphase flow, and fluid behavior methodologies to help ensure data quality and consistency between steady-state and transient analyses. As mentioned, the PIPESIM simulator may be operable in combination with one or more flow models such as, for example, the version of the OLGA S flow model from OLGA 2023.1 (e.g., the OLGA framework).

As an example, a framework may provide for automated production network forecasting workflow that facilitates updating of network models with operational data, running batch simulations, retrieval and analysis of results.

As an example, a framework may operate as a production advisor that improves oil and gas production network forecasting. As an example, a framework may provide for uploading PIPESIM simulator models and forecasts, which may reduce reliance on manual processes such that the framework may expeditiously run simulations to gain valuable insights (e.g., through output as commands, visualizations, etc.). As an example, a framework may empower control over various parameters, enabling optimization of fluid network performance. As an example, a framework may provide flexibility that allows for exploring various scenarios, along with adaptation to new data. As an example, a framework may provide for seamless results export capabilities (e.g., for offline analysis, etc.). As explained, a framework may provide for improved forecasting such that the framework can streamline efficiency in production network forecasting where results thereof may be utilized for one or more purposes, which can include control of one or more field operations, etc.

As an example, a framework may provide for improved user experience as to a multiphase flow simulator. For example, such a framework may improve user experience of the PIPESIM simulator, for example, by filling a gap in functionality within a workflow. Such a gap may exist in a manner that depends on manual interactions with multiple applications. For example, consider a gap that depends on a spreadsheet application (e.g., EXCEL, Microsoft Corporation, Redmond, WA) and the PYTHON Toolkit (PTK) (SLB, Houston, TX). Such a gap, as manually performed, demands use of multiple applications and transfers, along with attention to formatting. As explained, a framework may provide for filling such a gap in an automated and/or semi-automated manner, which may be selected where a human in the loop (HITL) may be, in some instances, beneficial for review, quality assurance, etc. As an example, an automated approach may provide for issuance of one or more command such as, for example, notifications, which may include notifications for HITL attention. In various instances, an HITL approach may be demanded for purposes of compliance, etc. (e.g., consider regulatory compliance). As explained, a framework may provide for automation of one or more aspects of a workflow associated with a fluid network (e.g., a fluid production network, etc.).

As to the PTK, it may serve as a framework application programming interface (API), for example, consider an API for the PIPESIM framework that may facilitate interactions with models. For example, the PTK may provide for interactions without instantiation of a particular graphical user interface (GUI). As an example, the PTK may help to streamline automation of modeling, such as, for example, building models, updating existing models, running simulations, and generating, accessing, formatting, etc., results (e.g., for a spreadsheet application, a visualization dashboard, etc.). In such an example, the PYTHON language may be utilized, noting that one or more APIs may utilize PYTHON and/or one or more other languages. As an example, JAVASCRIPT Object Notation (JSON) (Oracle Corp., Austin, TX, see also Ecma International, Geneva, Switzerland) may be utilized. As an example, PTK may provide for utilization of one or more machine learning techniques, models, etc. (e.g., in PYTHON, etc.) in combination with a simulation framework (e.g., the PIPESIM framework, etc.), which may provide for leveraging multiphase flow simulation capabilities within a framework (e.g., an application for assessment, control, etc., of a fluid network).

As an example, a fluid network framework may operate as a network analyzer that may provide for various tasks such as, for example, forecasting and optimizing oil and gas pipeline networks.

As an example, a framework may operate to simplify and accelerate network forecasting simulations in a manner that reduces demand for manual and time-consuming processes. A framework may offer a user-friendly, map-based interface where a user or machine may upload one or more pipeline network models and one or more production forecasts. Through streamlining data loading functionality, a framework may provide for expeditious uploading of production forecasts for a large number of wells, facilitating batch simulations, enhancing result reporting, etc.

As an example, a framework may help users gain insights through visualization of simulation results, enabling proactive identification of potential bottlenecks within production systems, detection of data inconsistencies, and evaluation of optimization potential. As an example, by leveraging field-proven physics models, a framework may empower users with comprehensive control over various parameters such as, for example, compression and pipeline diameters, facilitating network performance optimization and help to ensure seamless operations.

As an example, a framework may provide flexibility to evaluate various scenarios by creating multiple versions of multiphase flow simulation models (e.g., PIPESIM simulator models, etc.) and/or by providing for assessment of alternative forecasts with one or more specific models of interest. As an example, as new data become available, a framework may be operable to readily upload revised forecasts and models and, for example, re-run one or more simulations to capture time-relevant insights (e.g., most current, data-based insights, etc.). As an example, a framework may provide for export of models and simulation results, for example, to help streamline an ability to perform one or more types of offline analyses and/or sharing of findings. In such an example, a framework may operate in an automated mode and/or in a semi-automated mode. For example, a framework may be operatively coupled to one or more other frameworks where output may be pushed or otherwise provided optionally along with one or more commands for performing one or more analyses by an operatively coupled framework.

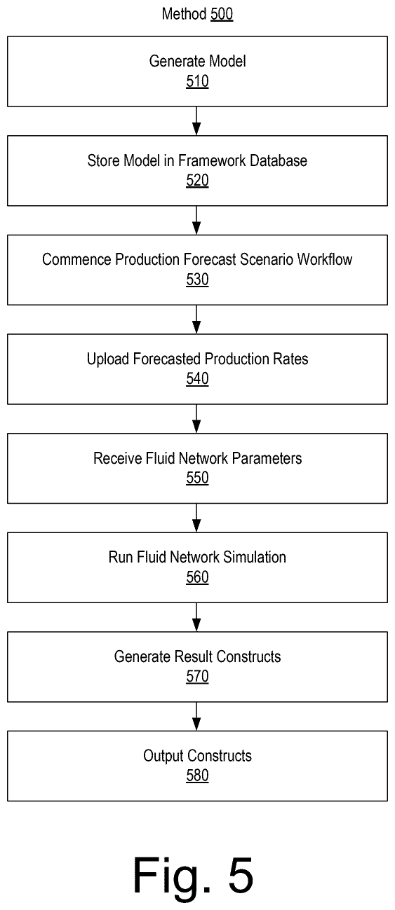

FIG. 5 shows an example of a method 500 that may be performed at least in part by a framework that may operate as a fluid network analyzer. As shown, the method 500 can include a generation block 510 for generating a network model (e.g., using a multiphase flow simulation framework, etc.), a storage block 520 for storing the model in a framework database (e.g., consider model and version, etc.), a commencement block 530 for commencing a production forecast scenario workflow, an upload block 540 for uploading forecasted production rates (e.g., from the workflow) according to one or more specified formats, a reception block 550 for receiving fluid network parameters (e.g., consider pipeline and facility parameters, such as, for example, one or more of maximum pressure for sinks (facilities), pressure, erosion velocity ratio (EVR) for flowlines, etc.), a run block 560 for running a fluid network simulation job (e.g., consider running the job using the framework that may operate in coordination with a simulation engine as a background process where, if appropriate, queuing may provide for submission of multiple simulation jobs that may provision resources as appropriate), a generation block 570 for generating result constructs (e.g., consider generation of one or more of charts, heatmaps, interactive graphics, etc., for one or more completed simulation jobs), and an output block 580 for outputting one or more constructs (e.g., consider generation of results suitable for output in one or more formats (e.g., EXCEL compatible, etc.)).

As an example, the method 500 may be performed in a cyclical manner where, for example, once a cycle is completed, one or more users may iterate to explore one or more different scenarios, for example, based on new production rates and/or one or more different parameters (e.g., pipeline parameters, facility parameters, etc.), which may be utilized for the same network model and/or for one or more different network models.

As an example, a framework may operate using various components, which may be operationally integrated by the framework using one or more techniques (e.g., application programming interfaces (APIs), add-ons, plug-ins, etc.). For example, consider a framework that may operationally control the PIPESIM simulator, a software development kit (SDK or tool kit) for the PIPESIM simulator (e.g., PIPESIM PYTHON SDK), etc. As an example, a framework may include framework code that may provide for rendering and operation of a front-end user interface (e.g., consider ANGULAR, INT GeoToolkit, SLB DLS, etc.). As an example, a framework may include a database schema (e.g., consider SQLite, etc.). As an example, a framework may include a programmatic interface (e.g., communication interface, etc.) with a front-end, database, and simulation API (e.g., consider a .Net Web API, etc.). As an example, a framework may include a programmatic interface (e.g., communication interface, etc.) with a simulation engine (e.g., consider a DJANGO Web API, PYTHON, etc.). As an example, a framework may provide for token-based licensing.

As mentioned, a simulator may be a multiphase flow simulator that may provide for interactions via an API, which may be available as part of an SDK or tool kit. In such an example, the SDK serves to provide extensibility, for example, to facilitate communication with simulator models directly (e.g., without demand for opening a user interface (UI)). For example, the PIPESIM PYTHON tool kit can provide for streamlining automation of building models from scratch, updating existing models, running simulations and returning results (e.g., in a spreadsheet format, etc.), which may be suitable for interactions with graphics engines for GUI generation (e.g., consider a visualization dashboard using PYTHON, etc.). As an example, a framework may provide for operational integration with one or more types of machine learning technologies (e.g., PYTHON and/or other libraries, etc.).

As an example, the PIPESIM simulator may be integrated in a manner that allows for building a model of an asset or assets, for example, connecting with reservoir and process simulators such as the ECLIPSE simulator, the INTERSECT simulator, Aspen HYSYS, Honeywell UniSim, KBC Petro-SIM, etc. As an example, a framework may provide for consumption of real-time data for online optimization.

As an example, a system may include one or more components, features, etc., of a SENSIA system (SENSIA LLC, Houston, Texas). As an example, a system may include one or more features of the QRATE HCC2 controller (SENSIA LLC), which may include a dedicated ARM microcontroller, embedded I/O, serial communications unit(s), Ethernet unit(s), one or more serial ports, one or more GPS units (e.g., consider a GNSS receiver for time synchronization), a video port (e.g., consider an HDMI port for edge application touch interface, etc.), one or more wireless option features, one or more modems (e.g., 5G, 4G LTE, WIFI, etc.), firmware, operating system, etc. As an example, such a controller may provide for running DOCKER containers (Docker, Inc, Palo Alto, California), etc. As an example, a system may include one or more processor-based components in the field, which may provide for framework execution. For example, consider a component that may provide for data acquisition, equipment control, interactions with one or more other components, etc. As an example, a field component may operate as an edge device, a gateway, etc., where, for example, one or more sites, wells, facilities, etc., may be operatively coupled to an edge device, a gateway, etc.

As an example, a framework may be operable with the PETREL framework (SLB, Houston, TX), for example, to offer well deliverability modeling, which may utilize the PIPESIM simulator to generate vertical flow performance (VFP) tables and perform nodal analysis. As an example, the AVOCET framework may be utilized to help manage production data and interface with the PIPESIM simulator for tasks such as, for example, model-based surveillance and optimization.

As an example, a framework may provide for operational coupling with the AVOCET Integrated Asset Modeler (IAM) (SENSIA LLC, Houston, TX), which may provide for combining PIPESIM simulator operations with reservoir simulator operations and/or one or more economic analysis tools (e.g., MERAK PEEP (Quorum Software, Houston, TX), etc.), which may provide for simulation and optimization of one or more assets.

As an example, one or more workflows involving gas lift operations may be performed, which may utilize, for example, the AVOCET Gas Lift Manager, as a gas lift surveillance and management framework that may consume real-time data for performance of online diagnostics and optimization (e.g., using the PIPESIM simulator, etc.). As explained, dynamic multiphase flow may be simulated using one or more simulators, where, for example, one or more OLGA dynamic multiphase flow simulator models may provide for simulation of transient flow, etc. As an example, a framework may leverage a conversion utility, for example, consider the PIPESIM simulator conversion utility that allows for export of models into the OLGA simulator.

As an example, a framework may utilize one or more of various components, platforms, other frameworks, libraries, languages, application programming interfaces (APIs), etc.

As an example, ANGULAR JAVASCRIPT (AngularJS) may be utilized, which is an open-source JAVASCRIPT-based web framework (Massachusetts Institute of Technology, Cambridge, MA) for developing applications that provides for client-side model-view-controller (MVC) and model-view-viewmodel (MVVM) architectures, along with components that may be used in web applications and progressive web applications.

As an example, one or more DJANGO Web APIs (Django Software Foundation, Huntersville, NC) may be utilized, which may be built using the DJANGO REST framework, which provides a flexible toolkit for building Web APIs.

As an example, SQLite may be utilized, which is a C-language library (public domain) that can be utilized to implement a self-contained SQL database engine.

As an example, a framework may utilize one or more .Net (e.g., .NET) tools (Microsoft Corp., Redmond, WA). For example, consider ASP.NET where endpoints may provide for automatically serializing classes to properly formatted JSON out of the box. JSON is a relatively lightweight, text-based format that may be utilized for various tasks. For example, consider use of JSON in workflows for storing data, exchanging data, etc., which may be part of one or more web services and/or application programming interfaces (APIs).

As an example, a visualization process may implement one or more of various features that can be suitable for one or more web applications. For example, a template may involve use of JSON and/or one or more other languages/formats. As an example, a framework may include one or more converters. For example, consider a JSON to PYTHON converter and/or a PYTHON to JSON converter. In such an approach, one or more features of a framework that may be available in one language may be accessed via a converter. For example, consider the APACHE SPARK framework (The Apache Software Foundation, Forest Hill, MD) that can include features available in a particular language where a converter may convert code in another language to that particular language such that one or more of the features can be utilized. As an example, a production field may include various types of equipment, be operable with various frameworks, etc., where one or more languages may be utilized. In such an example, a converter may provide for feature flexibility and/or compatibility.

As an example, a graphics engine may include one or more features of a graphics engine such as an OpenGL graphics engine (Khronos Group, Beaverton, OR). OpenGL is a cross-language, cross-platform API for rendering 2D and 3D vector graphics. The API may be used to interact with one or more graphics processing units (GPUs), to achieve hardware-accelerated rendering. As an example, one or more features of a VULKAN graphics engine (Khronos Group, Beaverton, OR) may be utilized. VULKAN graphics is a low-level low-overhead, cross-platform API and open standard for 3D graphics and computing that may provide more control over GPUs in comparison to OpenGL. VULKAN graphics may support a wide variety of GPUs, CPUs and operating systems, while be capable of interactions with multi-core CPUs.

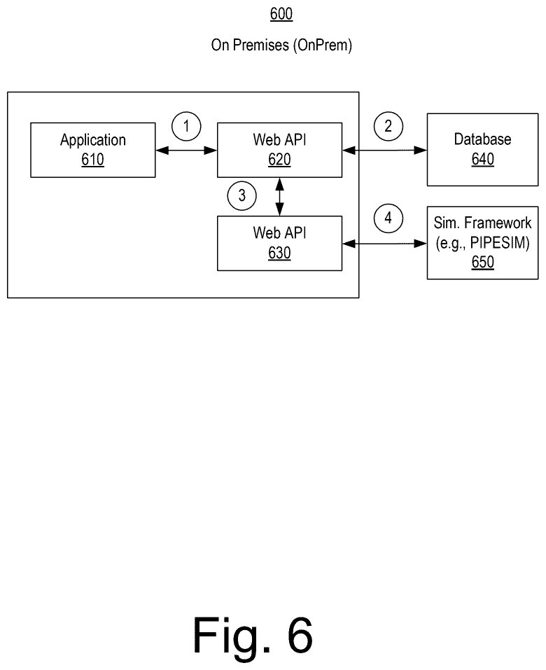

FIG. 6 shows an example of a system 600 that includes various components that may be suitable for on-premises implementation (e.g., “OnPrem”). As shown, the system 600 can include an application 610 (e.g., an ANGULAR application) operatively coupled to a Web API 620 (e.g., a .Net Web API) and another Web API 630 (e.g., a DJANGO Web API) where the Web API 620 (e.g., .Net Web API) provides for interactions with a database 640 (e.g., SQLite, etc.) and where the Web API 630 (e.g., a DJANGO Web API) provides for interactions with a simulation framework 650, which may be a multiphase flow simulator (e.g., the PIPESIM simulator, etc.).

In the example of FIG. 6, numbers in circles, 1 to 4, indicate an example of a workflow that may be implemented by the system 600. For example, per the circle 1, the application 610 may interact with the Web API 620 to cause interactions with the Web API 630 and the database 640, per the circles 2 and 3, where the interactions with the Web API 630 cause interactions with the simulation framework 650 per the circle 4. In such a workflow, results may be generated and transmitted to the application 610, which may provide for assessments, control, etc.

In the example of FIG. 6, the system 600 may be implemented in an on-premises manner (e.g., “OnPrem”). As shown, various components within a box may be operable with a database and/or a simulator. As an example, one or more features, components, etc., of the system 600 may be instantiated on-premises and/or instantiated in a remote environment, such as, for example, a cloud platform environment (e.g., with compute and memory resources). As an example, an on-premises implementation at one or more sites in a field may provide for robust local assessments over one or more portions of a network (e.g., surface network, etc.) and, for example, control of one or more pieces of equipment in the field.

As an example, one or more virtual resources may be available at a site or sites, which may include, for example, a virtual flowmeter (VFM), which may be instantiated within a unit (e.g., an edge device, a gateway, etc.). As an example, a site or sites may include one or more edge-based multiphase flow simulators, which may provide for running simulations. In such an example, an edge-based multiphase flow simulator may provide for local implementation of various features of the PIPESIM framework. As an example, such a simulator may be part of or operatively coupled to a VFM (e.g., in an edge device or other unit). As an example, a VFM may provide for acquisition of flow data in the absence of an actual flowmeter, which may be relatively costly to install and/or maintain; noting that one or more sites, etc., may include one or more flowmeters (e.g., multiphase flow meters (MPFM), etc.). As explained, field equipment may include one or more of various types of sensors, which may include, for example, pressure sensors, flowmeters, etc.

As explained, in instances where a number of scenarios (e.g., whether concerning parameter variations, model variations, etc.) are to be considered, a framework may provide for at least in part simultaneous execution of simulations in a manner that may involve provisioning of resources (e.g., consider provisioning of compute resources locally, in a cloud platform, etc., to execute one or more simulation engines to handle the number of scenarios). In various instances, results from a scenario may indicate that one or more other scenarios, which may be under execution, may be no longer relevant such that they may be canceled to thereby free resources. As an example, a framework may provide for such decision-making to effectively manage computational resources. For example, consider selection of a region of a surface fluid network where one or more local units may be leveraged for purposes of generating simulation results, acquiring measurements, implementing control, etc. As an example, a local multiphase flow simulator at one site may be leveraged for performing computations related to another site or site.

As an example, emissions may be taken into account, which may involve emissions from one or more sources, which may be from venting, flaring, equipment operation, travel to and/or from one or more sites using a vehicle, etc.

As an example, a framework may operate in an intelligent manner to generate results and to implement control. In such an example, the framework may provide for mitigation of issues, extension of service life (e.g., reduced erosion, etc.), achievement of one or more goals (e.g., production goals, etc.), etc. As an example, a framework may provide for optimizing field operations, for example, as to one or more portions of a network (e.g., a surface network, etc.).

As an example, a framework may utilize one or more technologies for interactions, which may be with one or more other frameworks, simulators, databases, display devices, etc. As an example, interactions may be human-to-machine, machine-to-machine, etc. As explained, a framework may provide for control of field equipment, with and/or without a human-in-the-loop (HITL). For example, consider one or more framework and choke interactions that may provide for control of one or more chokes in a field where control of a choke may provide for flow and/or pressure control.

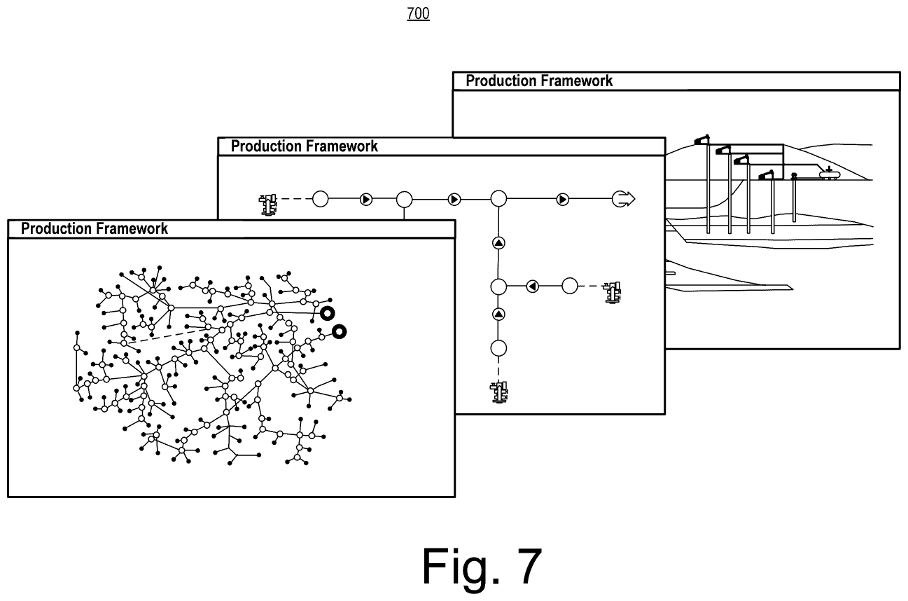

FIG. 7 shows examples of GUIs 700 that may be rendered to a display as part of a workflow implemented at least in part by a fluid network framework. As explained, a framework may operate as a network analyzer that can simplify and accelerate network forecasting simulations, reducing demands for manual and time-consuming processes. As an example, one or more map-based interfaces may be rendered that provide for uploading fluid network models and production forecasts. Such an approach can streamline data loading functionality in a manner that allows a network analyzer to enable swift uploading of production forecasts for a large number of wells, facilitating batch simulations, and enhancing result generation and output.

As explained, GUIs may provide for visualization of simulation results, enabling proactive identification of potential bottlenecks within production systems, detection of data inconsistencies, evaluation of optimization potential, etc. As explained, a framework may leverage field-proven physics models with comprehensive control over parameters such as, for example, compression and pipeline diameters, facilitating network performance optimization and helping to ensure seamless operations.

As explained, a framework may provide flexibility to evaluate various scenarios, for example, by creating multiple versions of simulator models or assessing alternative forecasts with specific models of interest. As explained, as new data become available, a framework may provide for uploading of revised forecasts and models and, for example, re-running simulations to capture the latest insights. As explained, a framework may provide for export of models and simulation results, which may facilitate one or more analyses, sharing of findings, control of field operations, etc.

As an example, a framework may provide for time and resource savings by automation of network simulation runs. Such a framework may provide for proactive identification of flow assurance issues and bottlenecks, model and scenario management for optimized network planning, and reduced IT support overhead.

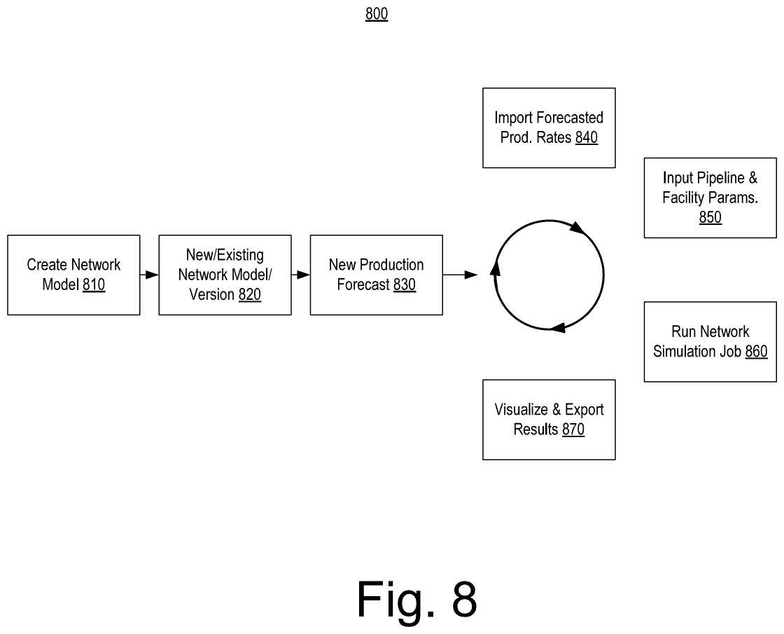

FIG. 8 shows an example of a method 800 that may include one or more features of the system 600 of FIG. 6. For example, consider a creation block 810 for creating a network model, an access block 820 for accessing a new or an existing network model and/or version thereof, a forecast block 830 for generating a new production forecast, an import block 840 for importing forecasted production rates, an input block 850 for inputting pipeline (PL) and facility parameters, a run block 860 for running one or more network simulation jobs using a simulator or simulators, and a visualization and/or export block 870 for visualizing and/or exporting results, control actions, etc. As an example, the method 800 may be performed along with rendering of one or more GUIs, which may provide for input, output and/or one or more other actions. As an example, a GUI may provide for controlling one or more pieces of field equipment as to performance of one or more field operations.

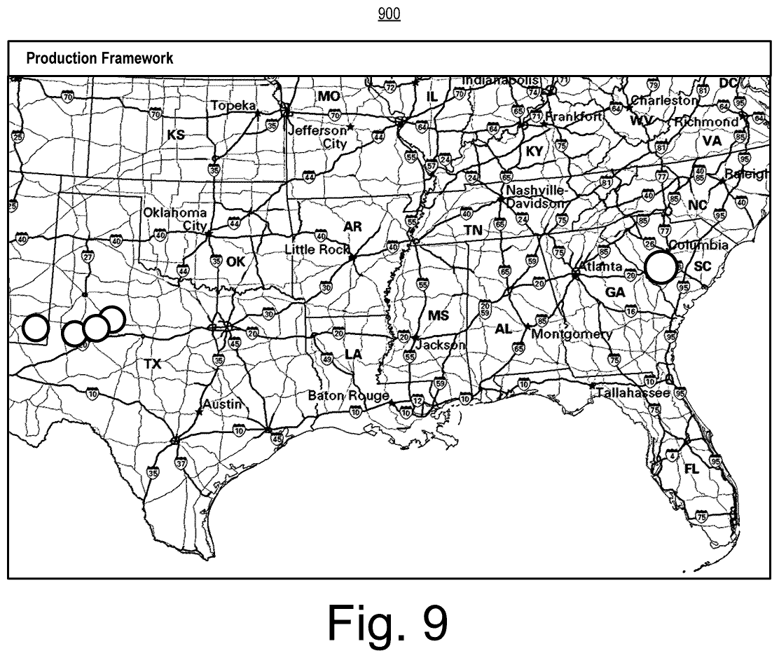

FIG. 9 shows an example of a GUI 900 that provides for rendering of graphics as to models in a map view. In the example of FIG. 9, a portion of the United States is shown, noting that non-U.S. geographies may also be amenable to assessment, control, etc.

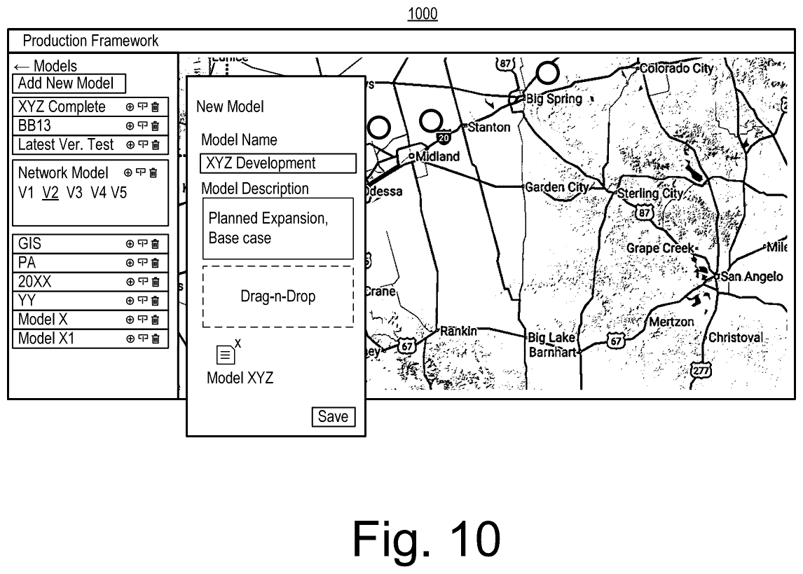

FIG. 10 shows an example of a GUI 1000 that provides for rendering of lists of models and associated information such as versions thereof. The GUI 1000 may provide for viewing existing models and versions, uploading versions to existing models, uploading new models, etc. For example, consider a panel that provides for accessing one or more models and/or adding a new model. In such an example, one or more indicators for a version or versions may be included. As shown, aspects as to renderings, maps, coordinates, etc., may be selected (see, e.g., GIS), along with temporal parameters and/or model numbers.

In the example of FIG. 10, a panel is overlaid for a new model where a model name may be specified along with a model description (e.g., planned expansion base case, etc.). As an example, a drag-n-drop feature may be provided for dropping a model into the panel for upload. As shown, a scenario may involve expanding an existing network where a process may commence with a base case that may be explored, optimized, etc. In the GUI 1000, a background map can include various markers, which may represent field equipment (e.g., flowlines, facilities, wells, well pads, etc.).

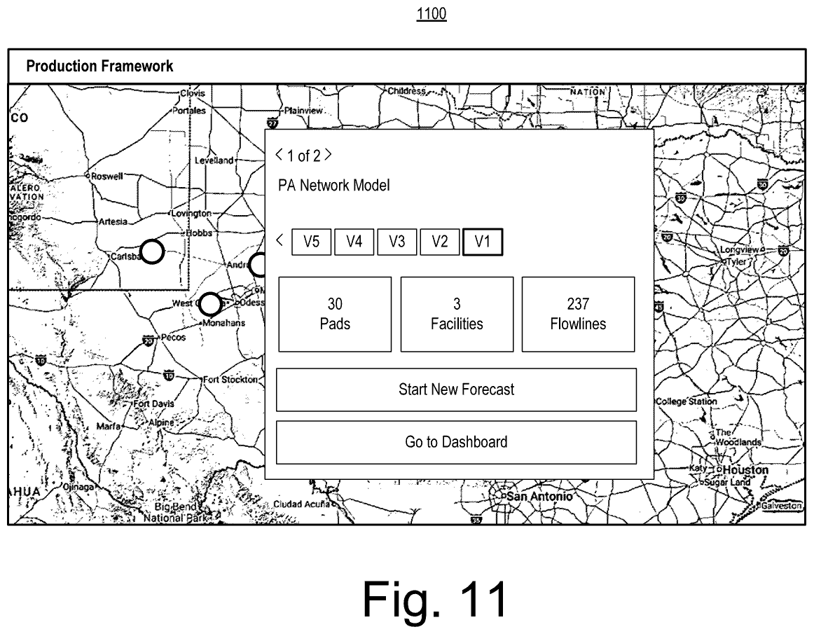

FIG. 11 shows an example of a GUI 1100 that provides for rendering of information as to a selected model, for example, in the form of a network model information card, which may be editable, exportable, etc. As shown, a dashboard graphical control may provide for rendering of a dashboard for the model.

In the example of FIG. 11, an overlaid panel may be a multipage panel that may be navigated. As shown, the overlaid panel can indicate versions, number of pads, number of facilities, number of flowlines (FL), etc. As shown, a graphical control may provide for commencing a new forecast. As explained, a GUI may provide for rendering of a map with locations of equipment, such that a user may be aware of geography. As explained, a perspective view may be renderable such as, for example, the perspective view of 403 of FIG. 4, which may include markers or actual imagery of facilities, flowlines, wells, well pads, etc.

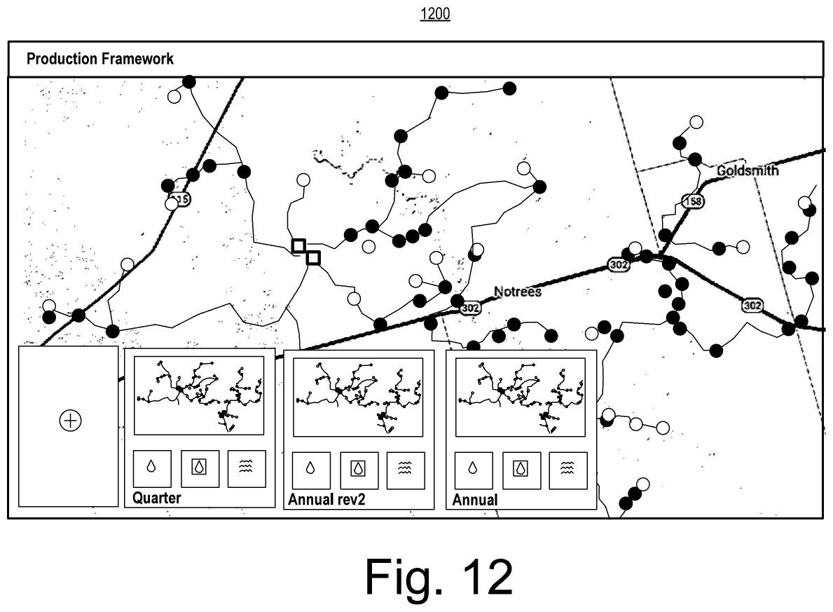

FIG. 12 shows an example of a GUI 1200 that provides for rendering of information associated with commencing a forecast or reviewing a completed forecast. As shown, a number of graphical elements may be rendered that may correspond to various forecasts, which may be associated with locations of various components on a map (e.g., wells, pipelines, facilities, etc.). As shown, forecasts may be with respect to time, a period of time, a revision, etc.

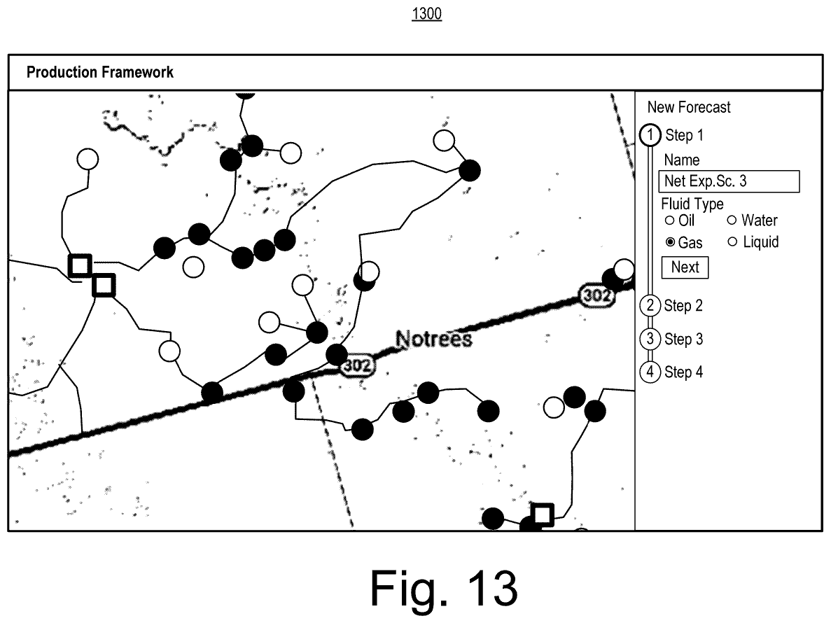

FIG. 13 shows an example of a GUI 1300 that provides for rendering of graphical controls for a new forecast scenario, which may involve naming, selecting or entering fluid type, etc. As shown, the GUI 1300 may provide for rendering graphics as to various actions to facilitate set up of a forecast scenario. In the example of FIG. 13, the scenario pertains to network expansion, which may, for example, be associated with one or more field operations (e.g., a new well, optimization, new equipment, etc.).

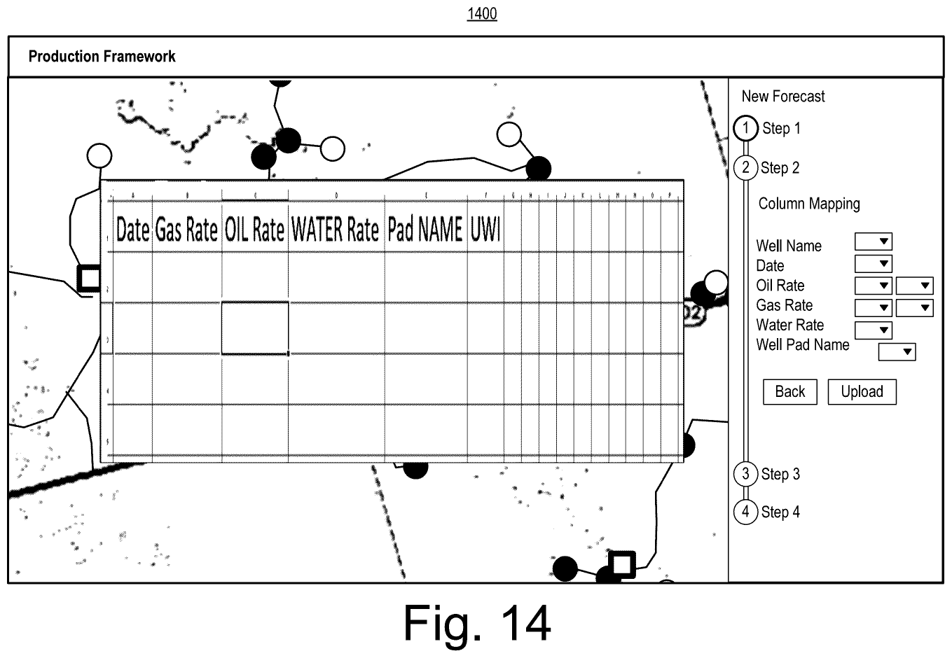

In the example of FIG. 13, a panel shows various steps (e.g., actions) that may be taken for forecasting. For example, consider a workflow that may involve four steps or actions, where, for example, the panel may indicate various options, inputs, parameters, units, etc., for each of the four steps or actions. FIGS. 14, 15, and 16, which follow, demonstrate how a series of GUIs may progress to improve a workflow where such a progression may occur responsive to action in one GUI such that another GUI is appropriately rendered. For example, the panel in FIG. 13, shown as a side panel, may automatically re-render as each step is performed such that a user is guided in a workflow, noting, for example, that a cursor interaction and/or other interaction may provide for selecting one of the steps such that an underlying framework may proceed to render a GUI for that step. For example, if a user is at step 2 and a corresponding GUI, the user may select a graphical control for step 1 and cause the underlying framework to return to step 1, either as an overview or to repeat or edit that prior step 1. In the examples of FIGS. 13, 14, 15, and 16, a GUI or GUIs may readily inform a user as to progress along a workflow and help guide a user where the GUI or GUIs are interactive and automatically responsive to input to cause a progression (e.g., forward, backward, etc.).

FIG. 14 shows an example of a GUI 1400 that provides for rendering of one or more data import features, which may be part of a forecast scenario. As shown, a column mapping graphical control may provide for options as to uploading where, for example, uploaded information and/or information to upload may be rendered in a panel, which may be associated with an application such as a spreadsheet application that may be instantiated (e.g., EXCEL, etc.). In such an approach, a user may readily verify and/or quality control various information. For example, a user may interact with one or more graphical controls to assure proper units of values, etc.

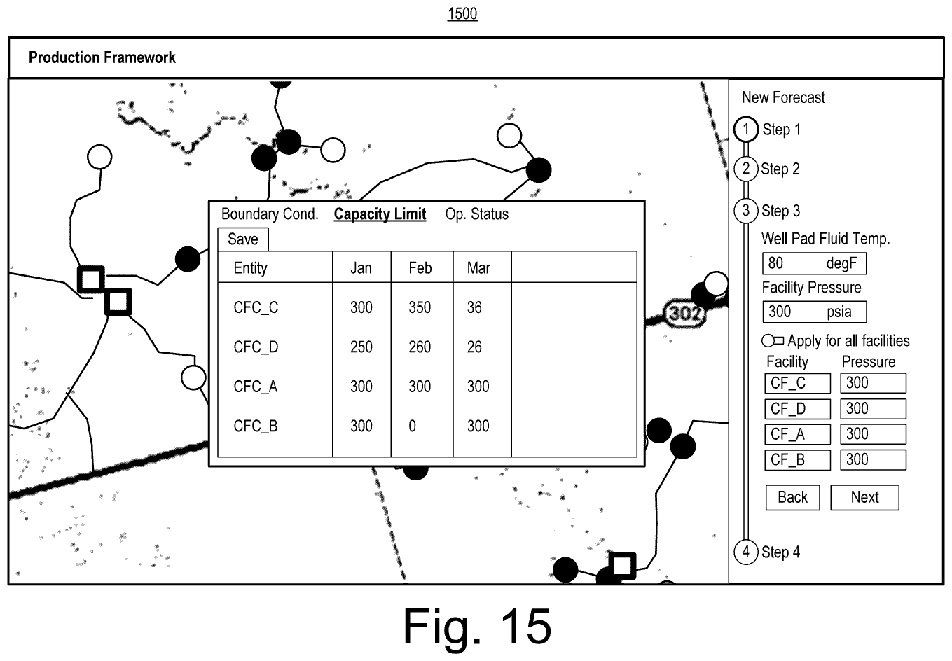

FIG. 15 shows an example of a GUI 1500 that provides for rendering of various graphical controls for setting facility constraints. For example, consider a GUI that can provide for handling of boundary conditions for simulation, capacity limits, operating status, etc. In the example of FIG. 15, capacity limit information is shown for various entities where such capacity limits, as constraints, may be specified with respect to time (e.g., for months of a year, etc.). In such an example, a panel may provide options for setting constraints to one or more facilities. For example, facilities may be commonly constrained or individually constrained using different constraints.

As shown, the GUI 1500 may provide for rendering of an overlay that provides for selection, review, revision, etc., of boundary conditions, capacity limits, operational status, etc. As to boundary conditions, as explained, sophisticated, complex models may provide for simulation of fluid flow in a network or a portion thereof. A boundary condition may be set for a simulator that may itself operate to constrain simulation results (e.g., at a node, etc.) or allow for freedom of a value in an unconstrained manner. A boundary condition may be a constant, a gradient, etc., that may be specified at a location or locations that correspond to a portion or portions of a network, which may be an actual physical network or a proposed network expansion or other network modification. As explained, a framework may provide for network optimization. As an example, a framework may provide for network control, which may be based at least in part on one or more network simulations (e.g., fluid flow simulation, etc.).

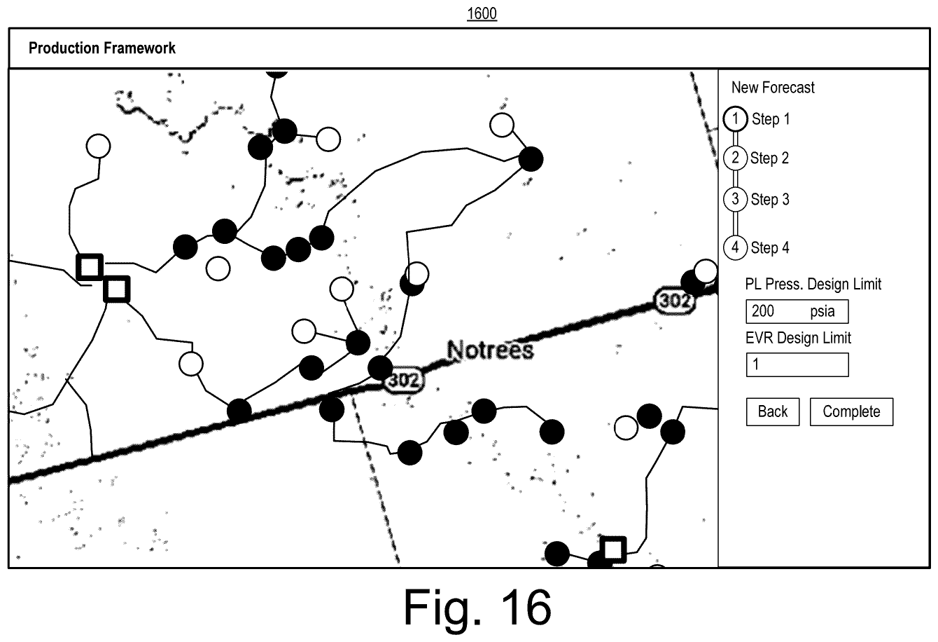

FIG. 16 shows an example of a GUI 1600 that provides for rendering of various graphical controls for parameters. For example, consider a GUI that can provide for rendering of pipeline pressure design limits, etc., which may be part of a scenario. As an example, one or more alternative scenarios may be generated, for example, using a feature that may provide for input of a range of pipeline pressure design limits where sampling occurs within that range to generate different scenarios, which, as explained, may be run at least in part in parallel, optionally with cancelation depending on results.

As shown, the GUI 1600 can include a panel with a graphical control for one or more design limits, for EVR, etc. As explained, EVR stands for erosion velocity ratio, which is a parameter in pipeline design and operation that may be used to assess potential for erosion of a pipeline's internal surface due to fluid flow. As an example, EVR may be computed by dividing an actual fluid velocity in a pipeline by a maximum allowable velocity for a specific fluid and pipe material, which may consider factors such as, for example, sand content, other erosive material, etc. As to numerical values for EVR, consider a value less than one indicating that the fluid velocity is below the threshold that causes erosion, and no erosion is expected; whereas, for a value of unity (one), that may indicate that the fluid velocity is at the threshold where erosion may begin. As to an EVR value greater than unity (one), that may indicate that the fluid velocity is above the threshold, and erosion is likely to occur. Erosion may be a factor in design, optimization, control, etc., of a network. As explained, a framework may provide for workflow implementation using various GUIs where EVR may be computed, taken into account, etc. In various instances, optimization may aim to provide for a suitable flow rate with an amount of erosion that does not jeopardize flow rate with respect to one or more goals, which may be defined for a period of time. As an example, in some instances, sand content may increase such that flow rate may need to be decreased. As an example, flow rate and sand entrainment may be related such that flow above a particular threshold flow rate may cause more sand to be produced from a producing well. As explained, one or more simulators may provide for simulating fluid flow, which may be in the presence of one or more types of solids that may impact EVR. As explained, an optimization process may take into account EVR.

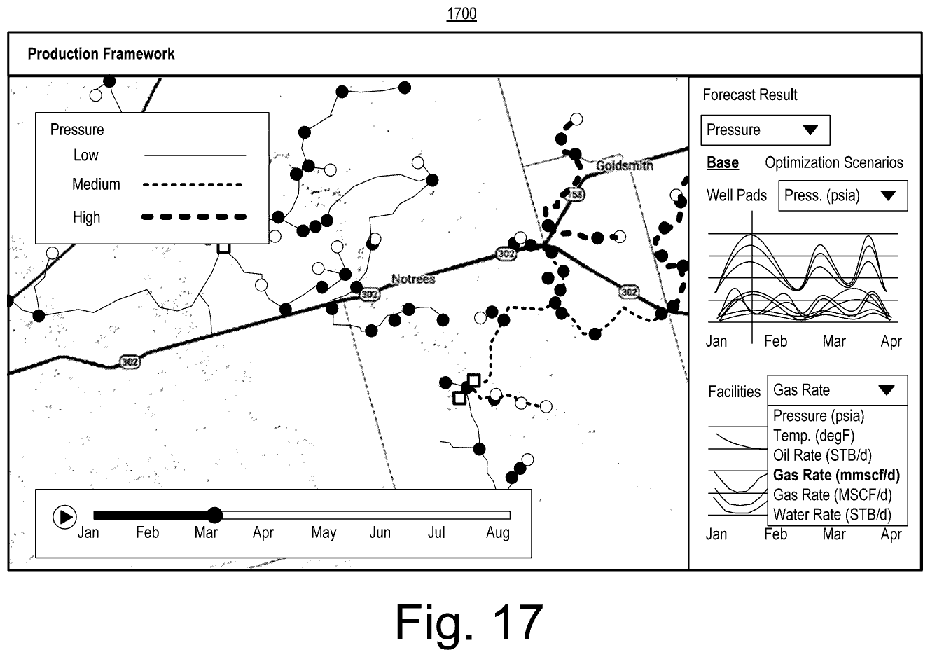

FIG. 17 shows an example of a GUI 1700 that provides for rendering of various results constructs, which may be in the form of heatmaps and charts. As an example, such a GUI may include various graphical controls for exploration of results. As an example, constructs may be provided on a live basis, for example, in synchronization with one or more simulators such that results may be presented in real-time as one or more simulations run, which may be run with respect to time. In such an example, a GUI may provide a graphical control that may provide for pausing and/or stopping one or more simulations. For example, if results extend to a particular point in time that is sufficient for operational decision-making, a user may cancel a simulation. As an example, where results for a scenario are deemed unsuitable, a simulation may be canceled (e.g., terminated) and a new scenario formulated and run.

In the example of FIG. 17, the GUI 1700 can include options to render results (e.g., result constructs, etc.) with respect to pressure and/or one or more other physical variables (e.g., gas rate, temperature, oil rate, etc.). As shown, results may be rendered for well pads, facilities, etc. As an example, results may be rendered with respect to time, which as mentioned, may be interactive with simulator execution. For example, consider a graphical control for progressing in time as to results, which may be akin to a media controller. In such an example, the graphical control may operate responsive to input via a human-machine interface (HMI) and/or via a machine-to-machine interface (MMI). For example, consider an approach where completion of a simulation triggers advancement of the GUI 1700 such that re-rendering occurs. In such an example, various indicators, graphics, etc., may be update. As shown, various pipelines may be rendered using color, graphics (e.g., dots, dashes, thickness, etc.) to indicate values as to pressure, which may be along a spectrum (e.g., consider a color spectrum), or for one or more classifications (e.g., low, medium, and high).

As shown, a GUI may provide for review of a base case or base scenario and/or one or more optimization scenarios. As an example, the GUI 1700 may provide for making comparisons between scenarios, which may be part of an optimization scheme. As an example, a framework may implement one or more optimization techniques to determine a likely optimal scenario, which may be an actual scenario or a scenario that may be run based on analysis of already run scenarios.

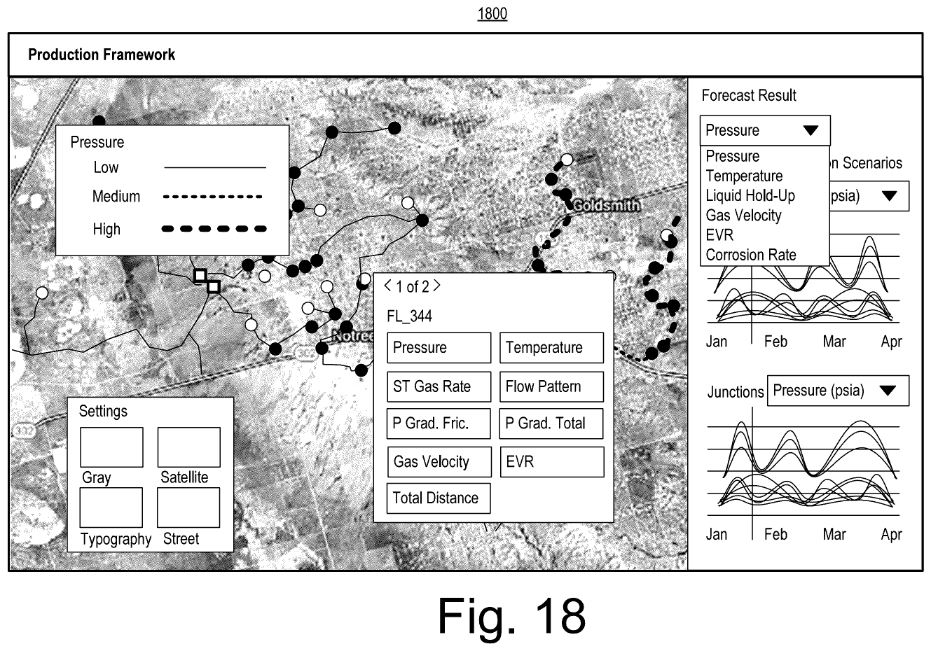

FIG. 18 shows an example of a GUI 1800 that provides for rendering of various graphical controls for map layers. For example, a GUI may include a map panel that can be rendered using one or more layers, which may include filtering, for example, to exclude and/or include certain information. As an example, a layer may include a satellite layer. As an example, a layer may include a drone layer, where one or more drones may provide for acquisition of imagery, which may be real-time imagery. As an example, one or more layers may correspond to sensor-based data, which may include information as to wind, rain, snow, heat, cold, etc. As an example, sensor-based data may include plume information as to one or more types of plumes, which may include emissions from flaring, emissions from leakage, etc. As an example, a layer may be an emissions layers whereby a scenario or scenarios may aim to optimize and/or otherwise tailor emissions from one or more portions of a fluid network, which may include wells, pipelines, facilities, etc.

As shown in the example of FIG. 18, a panel may provide for rendering of pressure, temperature, gas rate, pressure gradient friction, gas velocity, total distance, flow pattern gas/liquid, pressure gradient total, EVR, etc. As an example, a panel may provide for emissions information, losses due to one or more factors that may increase emissions (e.g., due to operation of one or more pumps, which may include one or more compressors, etc.). As to optimization, it may be performed with respect to one or more goals. For example, a goal may be to optimize production with minimal energy input as to equipment that may help to move fluid in a fluid network. As an example, a map may provide for interactions whereby a click on a site can cause rendering of information for that site, which may be generated using actual data, simulated data, etc.

As shown in the example of FIG. 18, a panel may provide for rendering of results (e.g., result constructs, etc.) with respect to pressure, temperature, liquid hold-up, gas velocity, EVR, corrosion rate, etc. As explained, results may be rendered for one or more aspects of a fluid network, which may be from wells, to wellsite equipment, to pipelines, to junctions (e.g., manifolds, etc.), to pumps, to processing facilities, etc. As an example, a GUI may render results for a number of scenarios such that scenarios may be readily compared and optionally ranked, which may be performed automatically by a framework with respect to one or more criteria.

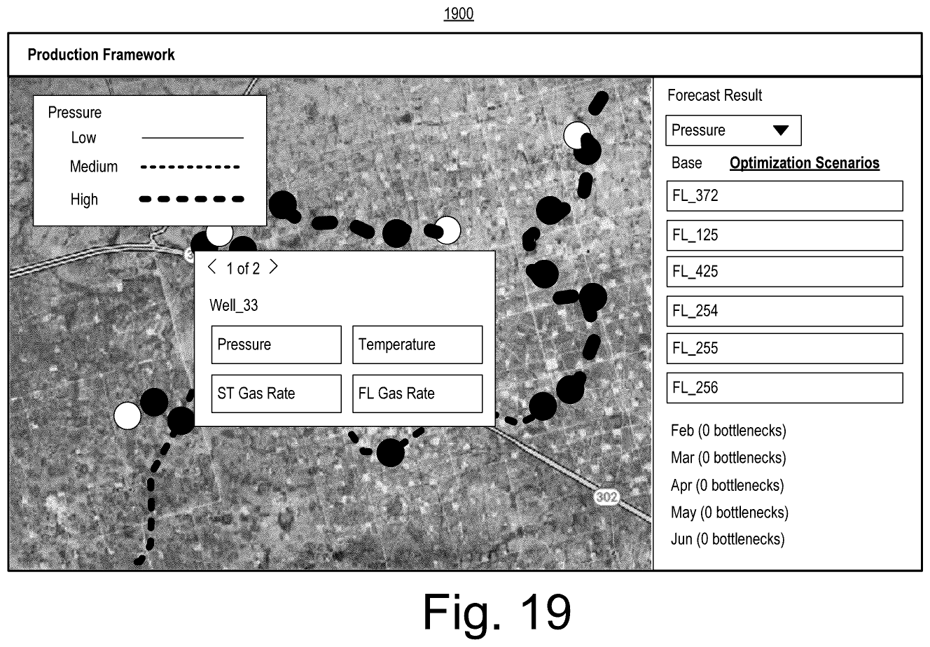

FIG. 19 shows an example of a GUI 1900 that provides for rendering of various graphical controls for exploration of bottlenecks, which may provide a basis for one or more optimizations. As shown, the GUI 1900 can include a graphical control for rendering of information associated with a well that may be selected on a map panel. As shown, information may indicate whether or not the well is active, along with well pressure, temperature, gas rate, etc. As explained, information rendered may be from a simulated scenario and/or from actual sensor-based readings.

As an example, a framework may provide for automatic detection of one or more bottlenecks. For example, the GUI 1900 includes a panel that includes a list of identified bottlenecks with respect to various flow lines (FLs) that may be identified, for example, according to pressure. As shown, each of the identified bottlenecks has a pressure of approximately 135 psia, which may be an indicator (e.g., a criterion, etc.) for bottleneck detection. As an example, one or more statistical techniques may be applied to actual data and/or simulated data to detect one or more actual or potential bottlenecks and/or to identify one or more solutions to reduce bottlenecking. For example, one or more scenarios may provide for optimization of a fluid network to address one or more bottlenecks and/or to reduce risk of bottlenecking. As indicated in the example GUI 1900, the forecast result panel includes base and optimization scenario options where addressing the identified (e.g., detected) bottlenecks (6 bottlenecks for a particular month) may provide for fluid network optimization. As an example, the month or months may include past, current and/or future months. For example, a framework may be operable to detect a future bottleneck whereby a scenario may be developed that can address the future bottleneck before it occurs. In such an example, a framework may provide for output of one or more commands, control parameter values, etc., to control operation of a fluid network and/or to modify a fluid network (e.g., via one or more equipment changes, etc.). In such an approach, a framework may provide for improved fluid network operation in a manner that reduces risks of bottlenecking. As an example, a framework may provide for fluid network debottlenecking for a producing field that may include identifying one or more fluid network bottlenecks and/or defining one or more mitigation solutions, which may include fluid rerouting, additions and/or subtractions of equipment, control of one or more pieces of equipment, etc.

As explained, a framework may provide for detection of one or more types of issues that may make a fluid network and/or operation thereof sub-optimal. For example, as mentioned, issues may include one or more of hydrate formation, wax and/or asphaltene deposition, emulsion formation, corrosion, scale formation, slugging, and sand production. As explained, such challenges tend to not be static in nature. As such, the dynamic nature of such challenges may be taken into account and coupled with forecasted production from one or more wells supported by one or more fluid networks. In combination, multiple issues may lead to reduced flow capacity, flow disruptions, equipment damage, increased operational costs, etc. As an example, a bottleneck may exist for one or more reasons and be viewed as an indicator as to sub-optimal fluid network design and/or operation. As an example, to address one or more issues, a framework may provide for scenario-based exploration as to design, operation, treatments, etc.

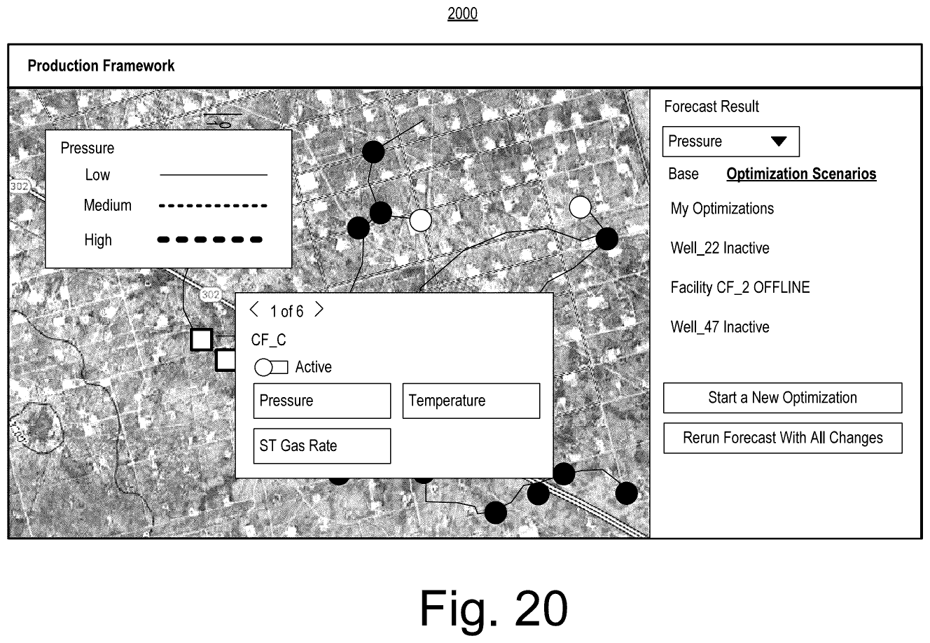

FIG. 20 shows an example of a GUI 2000 that provides for rendering of various graphical controls for creating and running one or more optimization scenarios. As shown, a panel may be rendered with a listing of optimizations, which may be for prior optimizations where a graphical control may be provided for creating a new optimization. As shown, an option may exist for rerunning one or more production forecasts with changes per a created scenario. As shown, scenarios for optimization may be directed to particular features of a fluid network such as a well being active or inactive, a facility being online or offline, etc.

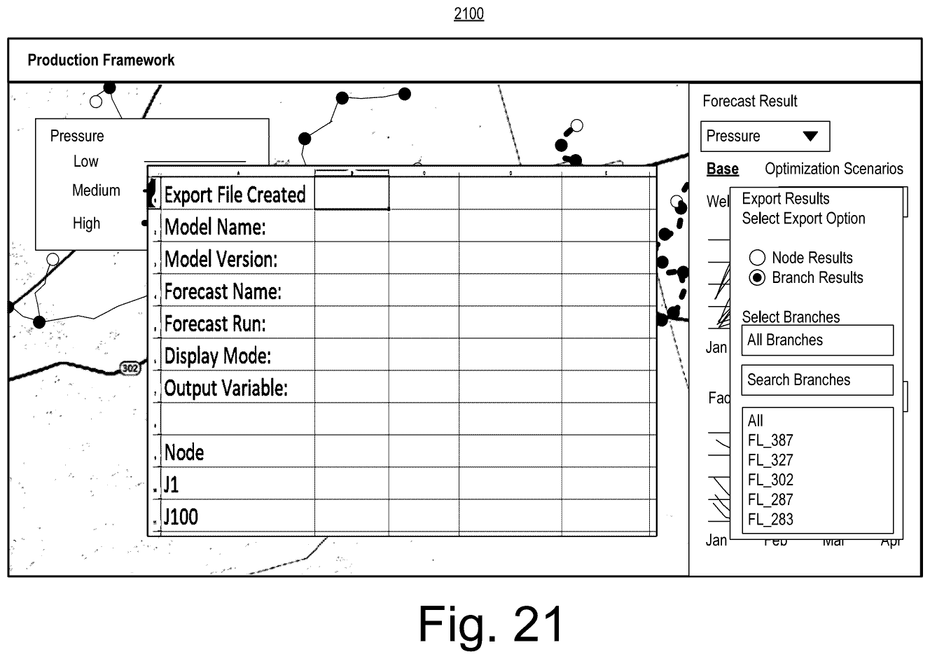

FIG. 21 shows an example of a GUI 2100 that provides for rendering of various graphical controls for output of results (e.g., result constructs, etc.). As shown, a panel may include options such as options to output results for nodes and/or branches where, for example, various nodes and/or branches of a fluid network may be selected. For example, consider a panel that includes a listing of nodes and/or branches where a graphical control or graphical controls provide for selecting one or more or all. In such an example, a data structure may be generated with information for the selected aspects of a fluid network. For example, consider a data structure that may be suitable for consumption by a spreadsheet application (e.g., EXCEL, etc.). In such an example, the spreadsheet application may be instantiated to render a visualization of information. For example, a framework may call for opening a file using a spreadsheet application where the spreadsheet application may present its own GUI for rendering to a display, which may be, for example, as an overlay to a framework GUI (e.g., the GUI 2100, etc.). Such an approach may provide for quality assurance where the information may be destined for use in one or more other workflows. For example, a user may view the information prior to providing it (e.g., as a file) for use in a workflow, etc.

As explained, a fluid network framework may provide for automated simulation runs, dynamic visual analysis of fluid network performance, tailoring unconventional upstream and/or midstream operator workflows, deployment as an on-prem framework that operatively couples to resources (e.g., database, simulator, etc.), etc. Such a fluid network framework may provide for time and resource savings due to automated workflows, proactive identification of flow assurance issues, model and scenario management for optimized planning, overviewing using map visualization and reporting for fast insights, etc.

As mentioned, a model may be utilized such as, for example, the aforementioned OLGA model (e.g., OLGA simulator). As an example, a framework may implement an online approach that can make use of one or more different simulator modes in different time scopes. For example, a real time mode can aim to simulate a system in real time and provide computed variables that may or may not be directly measurable. A real time mode may make use of a subset of measurements, for example, to close model boundaries and estimate tuning parameters so that so that selected model variables match or minimize deviations to the corresponding measurements.

As an example, a framework may utilize one or more inferred variables from a real time model as part of an objective (e.g., as a measured variable). As an example, a real time model can dump snapshots regularly where a snapshot can be loaded into one or more additional simulator modes with a corresponding model of the system where such modes can include look-back and look-ahead.

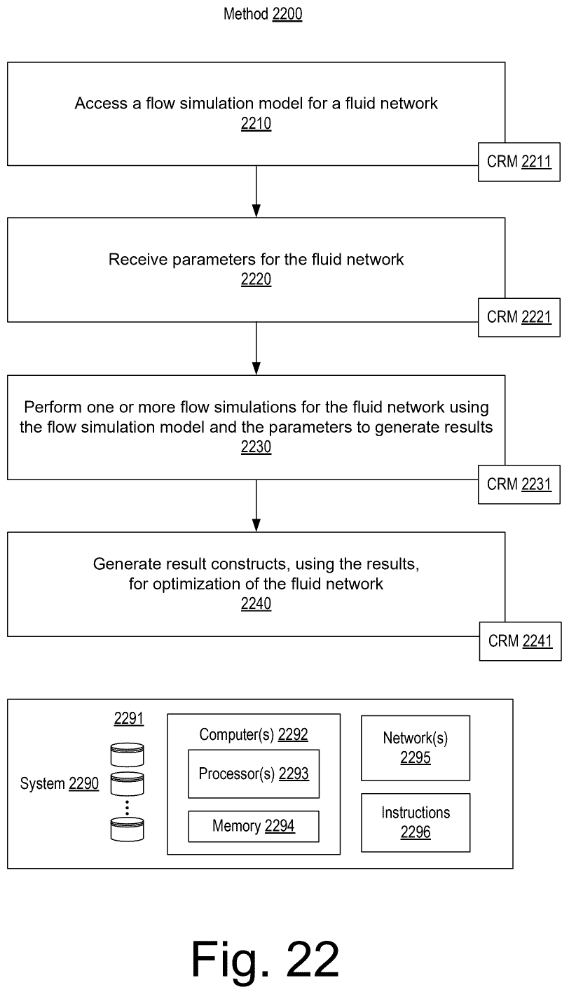

FIG. 22 shows an example of a method 2200 that includes an access block 2210 for accessing a flow simulation model for a fluid network; a reception block 2220 for receiving parameters for the fluid network; a performance block 2230 for performing one or more flow simulations for the fluid network using the flow simulation model and the parameters to generate results; and a generation block 2240 for generating result constructs, using the results, for optimization of the fluid network.

In the example of FIG. 22, a system 2290 is shown that includes one or more information storage devices 2291, one or more computers 2292, one or more networks 2295 and instructions 2296. As to the one or more computers 2292, each computer may include one or more processors (e.g., or processing cores) 2293 and memory 2294 for storing the instructions 2296, for example, executable by at least one of the one or more processors. As an example, a computer may include one or more network interfaces (e.g., wired or wireless), one or more graphics cards, a display interface (e.g., wired or wireless), etc.

The method 2200 is shown along with various computer-readable media blocks 2211, 2224, 2231 and 2241 (e.g., CRM blocks). Such blocks may be utilized to perform one or more actions of the method 2200. For example, consider the system 2290 of FIG. 22 and the instructions 2296, which may include instructions of one or more of the CRM blocks 2211, 2221, 2231 and 2241. As an example, the system 2290 or a portion thereof may be a controller, a framework operatively coupled to a controller, etc. As an example, the method 2200 of FIG. 22 or a portion thereof may be implemented and/or use one or more application programming interfaces (APIs). As an example, one or more of a model API, a data API, a data storage API, an actuator API, etc., may be utilized. As an example, the method 2200 may be executable within the DELFI environment (SLB, Houston, TX) or operatively coupled to the DELFI environment. As an example, the method 2200 of FIG. 22 may be implemented on an edge computing device in the field that may be coupled to a network, at least for data acquisition and control.

As an example, a method can include accessing a flow simulation model for a fluid network; receiving parameters for the fluid network; performing one or more flow simulations for the fluid network using the flow simulation model and the parameters to generate results; and generating result constructs, using the results, for optimization of the fluid network. In such an example, the flow simulation model may be or include a multiphase flow simulation model.

As an example, a fluid network can include at least one pipeline in fluid communication with at least one well and in fluid communication with at least one fluid processing facility.

As an example, a method may include receiving operational data for a fluid network and updating a flow simulation model using at least a portion of the operational data.

As an example, one or more flow simulations may include multiple flow simulations for different scenarios defined by different values of parameters of a fluid network. In such an example, performing one or more flow simulations may include instructing a flow simulator to perform the multiple flow simulations.

As an example, a method may include, based at least in part on result constructs, identifying at least one bottleneck. For example, consider identifying at least one bottleneck that includes an existing bottleneck in the fluid network and/or at least one bottleneck that includes a potential future bottleneck in the fluid network.

As an example, a method may include issuing at least one command for control of a fluid network to address at least one bottleneck.

As an example, a method may include identifying one or more bottlenecks utilizing pressure values. In such an example, the pressure values may include at least one simulated pressure value.

As an example, a method may include receiving a production forecast for a fluid network. As an example, one or more flow simulations may correspond to one or more production forecast scenarios. In such an example, a method may generate result constructs that may provide for comparing production forecasts for a plurality of different production forecast scenarios for optimizing a fluid network.

As an example, result constructs may be or include one or more data structures consumable by a graphics engine for rendering one or more graphical user interfaces to a display.

As an example, result constructs may be or include one or more data structures consumable by a graphics engine for rendering of one or more of heat maps and charts to a display.

As an example, a method may include optimizing a fluid network by one or more of controlling operation of the fluid network and altering equipment of the fluid network.

As an example, a system can include a processor; memory accessible by the processor; and processor-executable instructions stored in the memory where the instructions include instructions to instruct the system to: access a flow simulation model for a fluid network; receive parameters for the fluid network; perform one or more flow simulations for the fluid network using the flow simulation model and the parameters to generate results; and generate result constructs, using the results, for optimization of the fluid network.

As an example, one or more computer-readable storage media can include computer-executable instructions executable by a computer, where the instructions include instructions to: access a flow simulation model for a fluid network; receive parameters for the fluid network; perform one or more flow simulations for the fluid network using the flow simulation model and the parameters to generate results; and generate result constructs, using the results, for optimization of the fluid network.

As an example, a computer program product can include one or more computer-readable storage media that can include processor-executable instructions to instruct a computing system to perform one or more methods and/or one or more portions of a method.

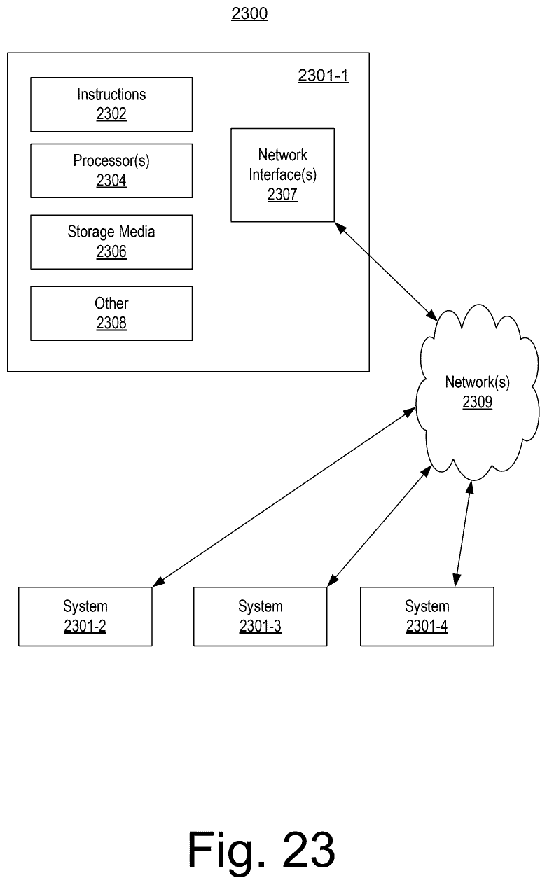

In some embodiments, the methods of the present disclosure may be executed by a computing system. FIG. 23 illustrates an example of such a computing system 2300, in accordance with some embodiments. The computing system 2300 may include a computer or computer system 2301-1, which may be an individual computer system 2301-1 or an arrangement of distributed computer systems such as systems 2301-2, 2301-3 and 2301-4. The computer system 2301-1 includes instructions 2302 that are configured to perform various tasks according to some embodiments, such as one or more methods disclosed herein. To perform these various tasks, the instructions 2302 can execute independently, or in coordination with, one or more processors 2304, which is (or are) connected to one or more storage media 2306 and optionally one or more other components 2308. The processor(s) 2304 is (or are) also connected to a network interface 2307 to allow the computer system 2301-1 to communicate over a data network 2309 with one or more additional computer systems and/or computing systems, such as 2301-2, 2301-3, and/or 2301-4 (note that computer systems 2301-2, 2301-3 and/or 2301-4 may or may not share the same architecture as computer system 2301-1, and may be located in different physical locations, e.g., computer systems 2301-1 and 2301-2 may be located in a processing facility, while in communication with one or more computer systems such as 2301-3 and/or 2301-4 that are located in one or more data centers, and/or located in varying countries on different continents).

A processor may include a microprocessor, microcontroller, processor module or subsystem, programmable integrated circuit, programmable gate array, or another control or computing device.

The storage media 2306 may be implemented as one or more computer-readable or machine-readable storage media. Note that while in the example embodiment of FIG. 23 storage media 2306 is depicted as within computer system 2301-1, in some embodiments, storage media 2306 may be distributed within and/or across multiple internal and/or external enclosures of computing system 2301-1 and/or additional computing systems. Storage media 2306 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices. Note that the instructions discussed above may be provided on one computer-readable or machine-readable storage medium, or alternatively, may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

It may be appreciated that computing system 2300 is an example of a computing system, and that computing system 2300 may have more or fewer components than shown, may combine additional components not depicted in the example embodiment of FIG. 23, and/or computing system 2300 may have a different configuration or arrangement of the components depicted in FIG. 23. The various components shown in FIG. 23 may be implemented in hardware, software, or a combination of both hardware and software, including one or more signal processing and/or application specific integrated circuits.

Further, the steps in the processing methods described herein may be implemented by running one or more functional components in information processing apparatus such as general-purpose processors or application specific chips, such as ASICs, FPGAs, PLDs, or other appropriate devices. Such components, combinations of these components, and/or their combination with general hardware may be utilized as part of a system and/or to implement one or more methods.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

Although only a few example embodiments have been described in detail above, those skilled in the art will readily appreciate that many modifications are possible in the example embodiments. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
accessing a flow simulation model for a fluid network;
receiving parameters for the fluid network;
performing one or more flow simulations for the fluid network using the flow simulation model and the parameters to generate results; and
generating result constructs, using the results, for optimization of the fluid network.

2. The method of claim 1, wherein the flow simulation model comprises a multiphase flow simulation model.

3. The method of claim 1, wherein the fluid network comprises at least one pipeline in fluid communication with at least one well and in fluid communication with at least one fluid processing facility.

4. The method of claim 1, comprising receiving operational data for the fluid network and updating the flow simulation model using at least a portion of the operational data.

5. The method of claim 1, wherein the one or more flow simulations comprise multiple flow simulations for different scenarios defined by different values of the parameters.

6. The method of claim 5, wherein the performing comprises instructing a flow simulator to perform the multiple flow simulations.

7. The method of claim 1, comprising, based at least in part on the result constructs, identifying at least one bottleneck.

8. The method of claim 7, wherein the at least one bottleneck comprises an existing bottleneck in the fluid network.

9. The method of claim 7, wherein the at least one bottleneck comprises a potential future bottleneck in the fluid network.

10. The method of claim 7, comprising issuing at least one command for control of the fluid network to address at least one of the at least one bottleneck.

11. The method of claim 7, wherein the identifying comprises utilizing pressure values.

12. The method of claim 11, wherein the pressure values comprise at least one simulated pressure value.

13. The method of claim 1, comprising receiving a production forecast for the fluid network.

14. The method of claim 1, wherein the one or more flow simulations correspond to one or more production forecast scenarios.

15. The method of claim 14, wherein the result constructs provide for comparing production forecasts for a plurality of different production forecast scenarios for optimizing the fluid network.

16. The method of claim 1, wherein the result constructs comprise one or more data structures consumable by a graphics engine for rendering one or more graphical user interfaces to a display.

17. The method of claim 1, wherein the result constructs comprise one or more data structures consumable by a graphics engine for rendering of one or more of heat maps and charts to a display.

18. The method of claim 1, comprising optimizing the fluid network by one or more of controlling operation of the fluid network and altering equipment of the fluid network.

19. A system comprising:
a processor;
memory accessible by the processor; and
processor-executable instructions stored in the memory wherein the instructions comprise instructions to instruct the system to:
access a flow simulation model for a fluid network;
receive parameters for the fluid network;
perform one or more flow simulations for the fluid network using the flow simulation model and the parameters to generate results; and
generate result constructs, using the results, for optimization of the fluid network.

20. One or more computer-readable storage media comprising computer-executable instructions executable by a computer, the instructions comprising instructions to:
access a flow simulation model for a fluid network;
receive parameters for the fluid network;
perform one or more flow simulations for the fluid network using the flow simulation model and the parameters to generate results; and
generate result constructs, using the results, for optimization of the fluid network.
